(19) United States
(12) Patent Application Publication
(10) Pub. No.: US 2010/0092780 A1
(43) Pub. Date: Apr. 15, 2010

(54) Optical Film, Processing Method of Optical Film and Processing Device of Optical Film

(76) Inventors: Yoshiaki Morinaga, Shizuoka (JP); Takeshi Tanaka, Hyogo (JP); Koji Nakashima, Hyogo (JP)

Correspondence Address: FRISHAUF, HOLTZ, GOODMAN & CHICK, PC, 220 Fifth Avenue, 16TH Floor, NEW YORK, NY, 10001-7708, US

(21) Appl. No.: 11/989,970

(22) PCT Filed: Jul. 12, 2006
(86) PCT No.: PCT/JP2006/313822

§ 371 Date: Feb. 4, 2008

(30) Foreign Application Priority Data
Aug. 9, 2005 (JP) 2005-2330708

(51) Int. Cl. B32B 9/04; B05D 3/10; B01J 19/10; C23C 16/52; B05C 1/06

(52) U.S. Cl. 428/411.1; 427/337; 427/560; 427/8; 118/264

(57) ABSTRACT

A processing method of an optical film comprising the step of: subjecting a long length roll-film continuously conveyed to a treatment so as to be brought in contact with a processing solution containing at least one type of gas selected from reducing gas and oxidizing gas.

### FIELD OF THE INVENTION

The present invention relates to optical film, a processing method of optical film and a processing device of optical film, in which wrinkles, color unevenness and coating defects such as a discontinuous streak, which are liable to be generated at the time of coating a functional layer such as an antireflection layer on long length roll-film, have been reduced.

### BACKGROUND OF THE INVENTION

In recent years, development of a thin and light notebook personal computer and a TV of a thin type and having a large image plane has made progress, and demand for a thinner, larger and higher quality protective film of a polarizer, which is utilized in a display such as a liquid crystal display, has come to be strong. Further, many liquid crystal image displays (such as a liquid crystal display) of such as a computer and a word processor, provided with an antireflection layer for improvement of visual recognition, or attached with an antiglare layer to scatter the reflective light by making a roughened surface, have been utilized.

An antireflection layer has been improved in various types and capabilities corresponding to applications, and a method in which various types of front surface plates provided with these functions are laminated on such as a polarizer of a liquid crystal display has been utilized to provide a display with an antireflection function for improvement of visual recognition (for example, refer to Patent Document 1). Optical film utilized as a front surface plate is generally provided with an antireflection layer formed by a coating, evaporation or spattering method.

Further, a thickness of utilized film is also required to be furthermore thinner to make a thinner display, or a width of optical film is also required to be wider to make a larger image plane. In particular, optical film having an excellent flatness is required in a large image plane; however, conventional optical film could not satisfy required flatness particularly with a wide and thin film and abrasion resistance was also insufficient in the case of a large area.

Particularly in the case of utilizing a metal oxide layer as an antireflection layer, coating unevenness is liable to be caused, and improvement thereof has been required. Particularly when a width of a film substrate becomes as wide as not less than 1.4 m, coating unevenness is extremely liable to be generated. Therefore required is to restrain coating unevenness such as wrinkles, color unevenness and discontinuous streaks.

Heretofore, it has been known that the surface of film is subjected to a dust removing treatment to decrease spot defects and streak defects due to foreign matters, and a wet type dust removing treatment has been known (for example, Patent Documents 2-3). However, these dust removing treatments can improve spot defects and streaks due to foreign matters to a certain extent, however, it is not sufficient and could not decrease coating defects such as wrinkles, color unevenness and discontinuous streaks.

[Patent Document 1] Unexamined Japanese Patent Application Publication No. (Hereinafter, referred to as JP-A) 2002-182005

[Patent Document 2] JP-A 8-89920

[Patent Document 3] JP-A 2001-38306

### SUMMARY OF THE INVENTION

### Problems to be Solved

An object of this invention is to provide optical film, a processing method of optical film and a processing device of optical film, having been improved with respect to coating defects such as wrinkles, color unevenness and discontinuous streaks, which are liable to be generated at the time of coating a functional layer such as an antireflection layer on a long length roll-film.

### Means to Solve the Problems

The above-described object of this invention can be achieved by the following constitutions.

Item 1. A processing method of an optical film comprising the step of:

subjecting a long length roll-film continuously conveyed to a treatment so as to be brought in contact with a processing solution containing at least one type of gas selected from reducing gas and oxidizing gas.

Item 2. The processing method of the optical film described in aforesaid Item 1, wherein the aforesaid reducing gas is hydrogen gas and the aforesaid oxidizing gas is ozone gas.

Item 3. The processing method of the optical film described in aforesaid Item 1 or 2, wherein a dissolved hydrogen concentration of the aforesaid processing solution is 0.1-2 ppm based on the total weight of the processing solution.

Item 4. The processing method of the optical film described in aforesaid Item 1 or 2, wherein an ozone concentration of the aforesaid processing solution is 0.1-100 ppm based on the total weight of the processing solution.

Item 5. The processing method of the optical film described in any one of aforesaid Items 1-4, wherein the processing solution is irradiated by ultrasonic waves while long length roll-film is brought in contact with the aforesaid processing solution.

Item 6. The processing method of the optical film, wherein provided is a process to continuously rub long length roll-film having been contacted with the aforesaid processing solution by an elastic body.

Item 7. The processing method of the optical film described in aforesaid Item 6, wherein a static friction coefficient of the surface of the aforesaid elastic body is not less than 0.2 and not more than 0.9.

Item 8. The processing method of the optical film described in aforesaid Item 6 or 7, wherein provided is a means to adjust a conveying position by detecting a position of the edge portion in the width direction of the aforesaid long length roll-film.

Item 9. The processing method of the optical film described in any one of aforesaid Items 6-8, wherein a temperature of the aforesaid processing solution is not lower than 30° C. and not higher than 70° C., and a temperature of the aforesaid elastic body is not lower than 30° C. and not higher than 70° C.

Item 10. The processing method of the optical film described in any one of aforesaid Items 6-9, wherein the aforesaid long length roll-film is rubbed by the aforesaid elastic body while pressing the rear surface of the film.

Item 11. The processing method of the optical film described in any one of aforesaid Items 6-10, wherein the surface to be processed of the aforesaid long length roll-film is wetted by the aforesaid processing solution in advance before being rubbed with an elastic body having been wetted by the processing solution.

Item 12. The processing method of the optical film described in Item 11, wherein the surface to be processed is wetted by a means to supply the aforesaid processing solution to the surface to be processed of the aforesaid long length roll-film.

Item 13. The processing method of the optical film described in Item 11 or 12, wherein a means to supply the aforesaid processing solution is provided between the aforesaid long length roll-film and the aforesaid elastic body.

Item 14. The processing method of the optical film described in any one of Items 1-13, wherein a period of the surface to be processed of the aforesaid long length roll-film being wetted is not shorter than 2 seconds and not longer than 60 seconds.

Item 15. The processing method of the optical film described in any one of Items 1-14, wherein a layer thickness of the aforesaid long length roll-film is not less than 30 μm and not more than 200 μm.

Item 16. An optical film characterized by having been processed by the processing method of the optical film described in any one of Items 1-15.

Item 17. A processing device of the optical film, which is provided with an elastic body rubbing means to rub long length roll-film with an elastic body having been wetted by a processing solution and a processing solution removing means to remove a processing solution on the surface of the long length roll-film after rubbing while the film is continuously conveyed, wherein provided is a means to make the processing solution contain at least one type of gas selected from reducing gas and oxidizing gas.

### EFFECTS OF THE INVENTION

According to this invention, provided can be an optical film, a processing method of the optical film and a processing device of the optical film which have been improved in decreasing coating defects such as wrinkles, color unevenness and discontinuous streaks which are liable to be generated at the time of coating a functional layer such as an antireflection layer on long length roll-film.

### BRIEF DESCRIPTION OF THE DRAWINGS

FIG. 1 shows an example of a processing method of the optical film according to this invention.

FIG. 2 shows an example of another processing method of long length optical film according to this invention.

FIG. 3 is an example of a schematic drawing of the case to perform ozone water ejection alone.

FIG. 4 is an example of a schematic drawing of the case to perform hydrogen water ejection alone.

FIG. 5 is a schematic drawing of an apparatus to rub one surface of long length roll-film, which is continuously conveyed, with an elastic body wetted by a processing solution.

FIG. 6 shows an example of a method to measure a static friction coefficient of an elastic body utilized in this invention.

FIG. 7 is an example of a schematic drawing to show arrangement positions of air nozzles and the blow direction of air.

FIG. 8 is another example of an apparatus to rub one surface of long length roll-film with an elastic body wetted by a processing solution.

FIG. 9 is an example of a schematic drawing to show another embodiment of an apparatus to rub one surface of long length roll-film with an elastic body.

### DESCRIPTION OF THE DESIGNATIONS

F: Long length roll-film
1: Elastic body
2, 2′: Guide roller
3: Processing solution tank
4: Processing solution
5, 6: Air nozzle
7: Dryer
8, 9: Processing solution supply means
10: Filter
11: squeeze pump
101: Conveying roller
102: Processing solution tank a
103: Conveying rollers
104: Air nozzle
105: Processing solution tank b
106: Ultrasonic oscillator
107: Ozone water ejection nozzle
108: Hydrogen water ejection nozzle

### DESCRIPTION OF THE PREFERRED EMBODIMENT

In the following, the most preferable embodiment to practice this invention will be detailed; however, this invention is not limited thereto.

As a result of extensive study, the inventors of this invention have found surprising effects that processing of long length roll-film being continuously conveyed to be brought in contact with at least one type of a gas selected from a reducing gas and an oxidizing gas, has improved decreasing of coating defects such as wrinkles, color unevenness and discontinuous streaks, which are liable to be generated at the time of coating a functional layer such as an antireflection layer on the long length roll-film, whereby a processing method of optical film of this invention has been achieved.

Particularly, the above-described processing solution is preferably hydrogen water in which the aforesaid reducing gas is hydrogen, or ozone water in which the aforesaid oxidizing gas is ozone. The effects of this invention can be achieved by contacting hydrogen water or ozone water on the surface of long length roll-film; the effects are considered to be because of some action on the long length roll-film surface and it is estimated due to modification of the film surface by an excess H radical reaction in the case of hydrogen water or due to removal of organic substances or reducing effect of a contact angle, of the film surface, by an oxidation reaction in the case of ozone water.

Further, the inventors have found that by utilizing a processing solution according to this invention and passing long length roll-film through a process to be continuously rubbed with an elastic body which is wetted with the processing solution, such as wrinkles, uneven tension and strain of the long length roll-film can be corrected to improve flatness of the long length roll-film and to decrease the aforesaid coating defects at the time of coating a functional layer such as an antireflection layer intervening such as a hard-coat layer.

Further, it has been found that the effect of this invention is enhanced by providing a means to detect the edge position in the width direction of the aforesaid long length roll-film and to adjust conveying position, in addition to a temperature of the aforesaid processing solution of this invention being not lower than 30° C. and not higher than 70° C., a temperature of the aforesaid elastic body being not lower than 30° C. and not higher than 70° C., the rear surface of the aforesaid long length roll-film being continuously rubbed with the aforesaid elastic body while being pressed, and only the surface to be processed of the aforesaid long length roll-film being wetted in advance with a processing solution before being rubbed with an elastic body wetted by the aforesaid processing solution.

In the following, this invention will be detailed.

A processing solution containing at least one type of a gas selected from a reducing gas and an oxidizing gas is not specifically limited. A reducing gas includes hydrogen gas and hydrocarbon gas such as methane, however, hydrogen gas is specifically preferred in this invention, and the processing solution is utilized as hydrogen water.

An oxidizing gas includes such as oxygen, ozone, hydrogen peroxide and carbon dioxide. These may be utilized alone or as a mixed gas. In this invention, an oxidizing gas is specifically preferably ozone gas, and processing solution is utilized as ozone water. In a processing solution of this invention, either one of a reducing gas or an oxidizing gas may be contained, or it is possible that both gases being contained at the same time.

As dissolving water utilized for hydrogen water and ozone water, utilized can be tap water, well water, industrial water, distilled water, pure water and ultra-pure water. It is preferable to utilize ozone or hydrogen being dissolved in distilled water, pure water or ultra-pure water. Specifically preferable is to dissolve ozone or hydrogen in ultra-pure water.

An example of water quality of preferable ultra-pure water is shown below.

TABLE 1

| | |
|---|---|
| Electric resistivity | not less than 18.0 MΩ · cm |
| Total organic carbon | not more than 10 μgC/liter |
| Number of micro-particles | not more than 10/ml |
| | (particle size of not more than |
| | 0.07 μm) |
| Number of micro organisms | not more than 10/liter |
| Dissolved oxygen | not more than 10 μgO/liter |
| Silica | not more than 1 μgSiO₂/liter |
| Sodium | not more than 0.01 μgNa/liter |
| Iron | not more than 0.01 μgFe/liter |
| Copper | not more than 0.01 μgCu/liter |
| Chloride ion | not more than 0.01 μgCl/liter |
| Hydrogen ion | 7 |
| concentration (pH) | |
| Redox potential | 450 mV (vs. NHE) |

A hydrogen concentration in hydrogen water is preferably not less than 0.1 ppm and not more than the saturation concentration, more preferably 0.1-2 ppm and specifically preferably 0.5-1.6 ppm.

As hydrogen water, those produced by a hydrogen water manufacturing apparatus, described in JP-A 2004-89871, are preferably utilized. Hydrogen water containing nitrogen described in JP-A 2004-281894 is also preferably utilized. Further, also utilized can be hydrogen water in which hydrogen is dissolved by use of a gas dissolution module described in JP-A 2000-317277. Hydrogen water generating apparatus available on the market, such as KHOW SYSTEM HS-40 manufactured by Kurita Industrial Co., Ltd. can be also utilized. Other than that, a hydrogen generator such as HS-06, HS-12 and HS-24 (manufactured by Kurita Industrial Co., Ltd.) or such as PHW-600-S, OHW-1800-S and PHW-3600-S (manufactured by Puretron Co., Ltd.) can be utilized.

On the other hand, an ozone concentration in ozone water is preferably 0.1-100 ppm, more preferably 0.1-50 ppm and specifically preferably 0.5-40 ppm. An ozone concentration in ozone water can be measured by use of ozone water concentration meter EL 500 type, manufactured by Ebara Corp.

A producing method of ozone water may be either a membrane dissolution method or a direct dissolution method. Ozone water produced by a method or a production apparatus such as described in JP-A Nos. 2000-180433, 2000-37695, 2000-219986, 2000-302413 and 2000-317277 is preferably utilized. Further, ozone water produced by a photochemical type ozone water supplier described in JP-A 2000-208464 can be utilized. Ozone water produced by a water electrolysis method is also utilized.

For example, ozone water can be supplied by use of an ozone water generator available on the market from Kurita Water Industries Ltd. and others, such as OS-12-10, OS-12-20 and OS-24-10 (produced by Kurita Water Industries Ltd.); QICK-OZONE AOD-ML30S and AOD-TH (produced by Ai Electronics Co., Ltd.); Electrolysis Ozone Water Generator POW-1010-S, POW-2020-S and POW-6005-S (produced by Puretron Corp.) and MKX 2000 (produced by Hatsumei Kobo Co., Ltd.).

It is also preferable to utilize hydrogen water as a processing solution after utilizing ozone water as a processing solution, and a processing solution prepared by mixing the both is also preferably utilized. Further, a processing solution may be also incorporated with hydrogen peroxide.

Although it depends on types and concentrations of substances contained in a processing solution, a processing solution having a redox potential of ±2,000 mV is preferably utilized.

A processing solution utilized in this invention is preferably added further with such as acid and alkali, and the pH and redox potential can be controlled thereby. For example, a redox potential of hydrogen water is preferably −300-−650 mV.

Acid and alkali, which can be added into a processing solution at the time of pH control by addition of acid and alkali, include such as carbonic acid gas, hydrochloric acid, nitric acid, sulfuric acid, acetic acid, formic acid, ammonia, tetramethylammonium hydroxide, sodium hydroxide, potassium hydroxide and ammonium carbonate. It is preferable that these are incorporated within the range of 0.1-5,000 ppm.

The dissolution water preferably has a pH of 4-11, and more preferably of 6-8.

A total organic carbon concentration (TOC) contained in a processing solution of this invention is preferably 0.001 μg/liter-1 mg/liter. The measurement method of TOC is not specifically limited; however, it is possible to be measured by use of a total organic carbon (TOC) automatic analyzer which is defined in JIS K0805. To control a TOC, it is possible to reduce a TOC in a processing solution by changing a circulation quantity, by increasing a replenishing quantity of fresh water, or by an irradiation treatment with ultraviolet rays. For example, it is possible to control a TOC by a method described in JP-A 2000-302413.

In a processing solution of this invention carbonic acid gas is preferably further contained, and the content of carbonic acid gas is preferably 0.01-100 mg/liter and more preferably 0.01-1 mg/liter. Particularly in the case of using ozone water, carbonic acid gas is preferably utilized because of easiness to maintain the ozone concentration. Further, a water-soluble organic substance can be also contained at 0.001-1,000 mg/liter. Specifically, listed are alcohols such as methanol, ethanol, butanol, isopropanol and n-propanol; and ketones such as acetone, methyl ethyl ketone and methyl isobutyl ketone.

In the following, the processing method of the optical film of this invention will be explained with reference to drawings. However, this invention is not limited thereto.

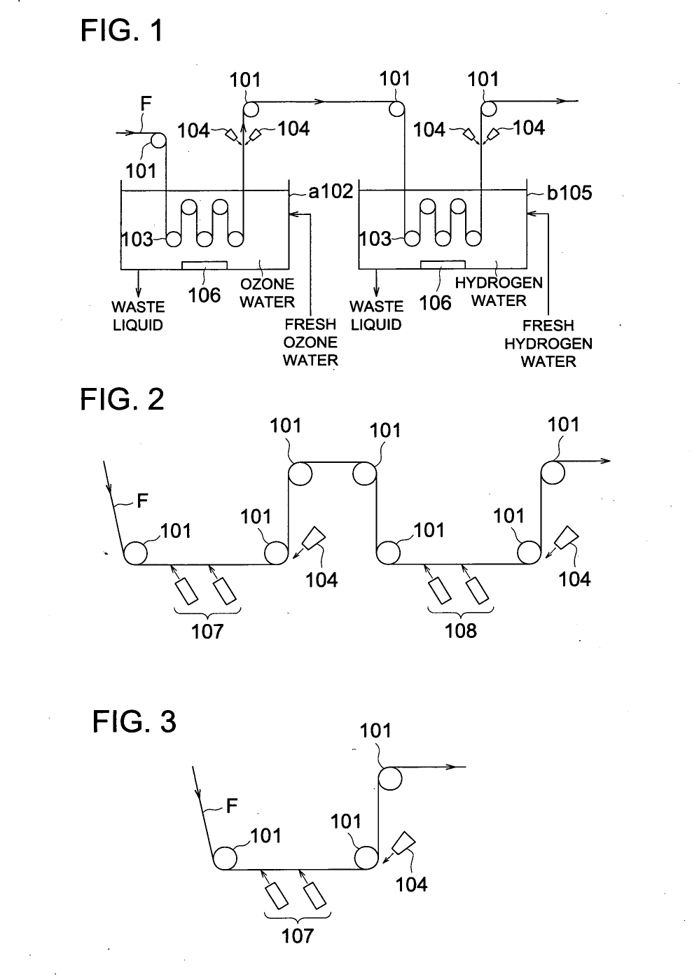

FIG. 1 shows an example of a processing method of long length optical film of this invention.

As an example of a preferred processing method for long length optical film, long length roll-film is preferably processed with hydrogen water after having been firstly processed with ozone water. The order of processing by ozone water and hydrogen water may be opposite, and each process can be alternately performed. Further, a processing solution which simultaneously contains ozone and hydrogen can be utilized.

In FIG. 1, long length roll-film F is immersed in “processing water tank a” of 102 which stores ozone water via conveying rolls 101, and pulled up from “processing solution tank a” to remove ozone water on the both film surfaces by “air nozzles” of 104 after having been processed with ozone water for a predetermined time by conveying roller group 103 comprising plural rollers. Next, the film is immersed into “processing tank b” of 105 which stores hydrogen water to be similarly processed by conveying rollers 1, being pulled up from “processing solution tank b” to remove hydrogen water on the both film surfaces by air nozzles 104, and is conveyed to the next process. An ultrasonic treatment is preferably employed in combination at the time of processing with hydrogen water. In FIG. 1, symbol 106 represents an ultrasonic oscillator. Ultrasonic radiation may be performed to ozone water, however, is preferably performed to hydrogen water. This ultrasonic oscillator 106 radiates ultrasonic waves on the surface of long length roll-film F to enable efficient treatment with such as hydrogen water. Herein, ultrasonic oscillator 106 is arranged to maintain a processing solution between the oscillator and long length roll-film so that ultrasonic waves are efficiently transmitted on the surface of long length roll-film F. Further, plural oscillators may be arranged, and in this case, the interval of ultrasonic oscillators is necessary to be determined so as to make uniform accumulation of ultrasonic waves from oscillators adjacent to each other.

As a frequency of ultrasonic oscillator 106, 10-100,000 kHz can be utilized. Further, a combination of plural oscillators which emit different frequencies or a oscillator capable of frequency modulation can be also utilized.

As an ultrasonic wave output power per unit area of the ultrasonic oscillator, the range of 0.1-2 W/cm² can be utilized. A distance from ultrasonic oscillator 106 to long length roll-film F has an optimum point due to the presence of a stationary wave, and is preferably set to a distance of an integer times of the following equation.

λ=C/f

wherein, λ is a wavelength, C is a transmitting speed of ultrasonic waves in the solution, and f is a frequency.

A period and a frequency of ultrasonic processing is preferably in the ranges of 1-100 sec and 10-100,000 kHz, and specifically preferably of 1-100 sec and 40-1,500 kHz.

An ultrasonic oscillator utilized includes such as WS-600-28N, WS-600-40N, WS-600-75N, WS-600-100N, WS-1200-28N, WS-1200-40N, WS-1200-75N, WS-1200-100N, N60R-M, N30R-M, N60R-M, W-100-HFMKIIN and W-200-HFMKIIN, produced by Honda Electronics Co., Ltd.; and products of Nippon Alex Corp.

A temperature of a processing solution of this invention can be set to 0-100° C., however, is preferably 30-70° C., and specifically preferably 30-60° C.

FIG. 2 shows an example of another processing method of long length optical film of this invention.

As a method to bring long length roll-film in contact with a processing solution, a processing solution can be put on long length roll-film being conveyed by ejection from a spray or a nozzle. As shown in FIG. 2, ozone water ejection nozzle 107 and hydrogen water ejection nozzle 108 can be utilized. Particularly, hydrogen water ejection nozzle 108 is preferably an ejection nozzle capable of ultrasonic ejection, and includes a megasonic nozzle (Pulsjet, produced by Honda Electronics Co., Ltd.) as an example. The size of a nozzle is not specifically limited, and one set of a bar-formed nozzle having a length of the film width may be utilized or plural sets of nozzles having a shorter length may be also utilized. Further it is also preferable to arrange plural sets of nozzles along the film conveying direction. A nozzle opening diameter is not specifically limited, however, is preferably 0.5-2 mm, and a supply quantity of a processing solution is not specifically limited, however, is preferably 1-100 ml/min·cm² against long length roll-film.

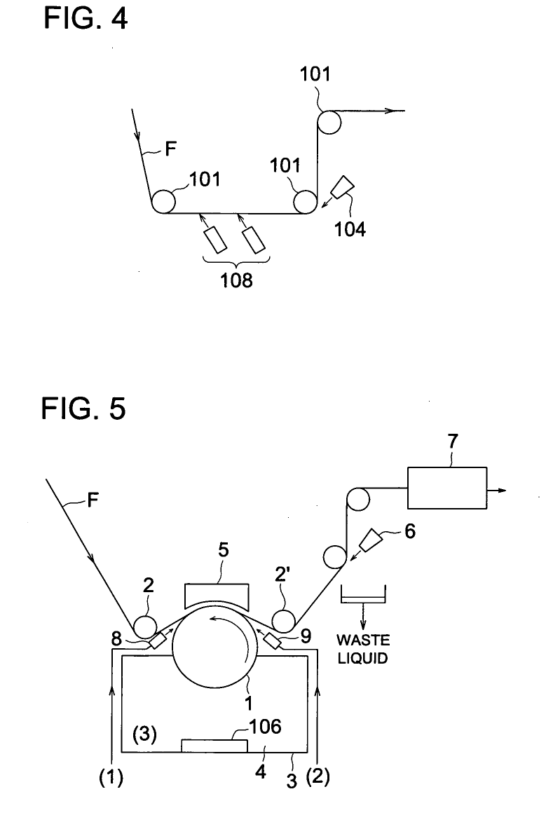

FIGS. 3 and 4 are schematic drawings of each case to independently perform ozone water ejection and hydrogen water ejection, respectively.

Further in this invention, a process to continuously rub log length film, which has been contacted with the aforesaid processing solution, with an elastic body is preferably provided. By continuous rubbing with an elastic body, it is possible not only to stably supply a processing solution on the long length roll-film surface but also to easily correct wrinkles, uneven tension and distortion of the surface, resulting in enhancement of effects of this invention.

FIG. 5 is a schematic drawing to show the whole apparatus to rub the one side surface of long length roll-film, which is continuously conveyed, by an elastic body wetted with a processing solution. Long length roll-film F is guided by guide roller 2 and rubbed by driven elastic body 1 (an elastic body roller). Driven elastic body 1 is kept wet by processing solution 4 stored in processing solution tank 3. Long length roll-film F is conveyed by guide roller 2′ after having been rubbed with an elastic body and the excess processing solution and foreign matters are removed by blowing air from air nozzle 6. Further, it is preferred to arrange air nozzle 5 on the opposite side of elastic body 1 and to prevent a processing solution from over flowing to the film back side by blowing air. Air nozzle 5 can control the pressing degree of long length roll-film onto an elastic body by adjusting air pressure, and it is preferred to continuously rub long length roll-film with the aforesaid elastic body while adjusting air pressure and pressing the rear surface of the film. As a means thereof, either the aforesaid air nozzle or such as a rear roller may be utilized, however, air nozzle 5 is preferably utilized with respect to preventing overflow of a processing solution to the film back side. Successively, long length roll-film is conveyed to dryer 7 to dry the both surfaces, and is conveyed to a coating process of a functional layer which is the next process.

Guide rollers 2 and 2′ guide traveling of long length roll-film F. Herein, guide rollers 2 and 2′ each are arranged at predetermined positions and it is important at this time that long length roll-film F is brought in contact with elastic body 1 with a wrap angle described later and that the same surface is guided so as to approach succeeding air nozzle 6.

Elastic body 1 is arranged between guide roller 2 and guide roller 2′ and rotated by drive of a motor, which is not shown in the drawing. This elastic body 1 is immersed at the bottom part thereof in processing solution 4 which is stored in processing tank 3. Long length roll-film F is continuously rubbed by this rotating elastic body 1 and wrinkles, uneven tension and distortion of the surface are corrected.

Herein, since elastic body 1 is immersed in processing solution 4 at the bottom part thereof, the surface is always kept wet with processing solution by rotation, and it is considered to be possible to correct wrinkles, uneven tension and distortion of the surface by rubbing the film surface while a processing solution intervenes between the elastic body and the film.

To keep a wet state of the elastic body surface, it is also preferable to provide a means to supply a processing solution onto the elastic body surface, and the processing solution supply means includes such as a processing solution ejection means.

Processing solution supply means 8 and 9 in FIG. 5 each are apparatuses to eject a processing solution comprising ozone water or hydrogen water onto the long length roll-film surface, respectively. Processing solution supply means 8 and 9 may employ either one set of a bar form having a length of the film width or plural sets of shorter length types. The opening diameter of the nozzle is not specifically limited, however, is preferably approximately 0.5-2 mm, and liquid sending quantity is preferably in a range of 5-50 L/min.

In this invention, it is an example of a preferred embodiment in which ozone water is ejected through processing solution supply means 8 and ozone water, or mixed water of ozone water and hydrogen water, is stored in processing solution tank 3, and further hydrogen water is ejected through processing solution supply means 9, however, it is not specifically limited to utilize which one of processing solution supply means 8 and 9, and processing solution tank 3 for which one of ozone water, hydrogen water or mixed water thereof.

Herein, elastic body 1 may rotate either following or reverse to the conveying direction, however, it is preferable to set the diameter and the rotation speed so as to keep an absolute value of a difference between line speeds of elastic body 1 and long length roll-film F within 5 m/min. The rotation speed is preferably 1-100 rpm and more preferably 5-60 rpm.

Conveying rate of long length roll-film F at the time of processing of this invention is generally 5-200 m/min and preferably 10-100 m/min.

Elastic body 1 is suitable for continuous production in the case of a roll form. Further, elastic body 1 may be constituted of either a single material such as natural rubber and synthetic rubber or a complex material such as a metal roller with rubber. For example, a metal roller of such as aluminum, iron, copper and stainless steel can be covered with polyamide such as 6-nylon, 66-nylon, copolymer nylon; polyester such as polyethylene terephthalate, polybutylene terephthalate and copolymer polyester; polyolefin such as polyethylene and polypropylene; polyvinyl halogenide such as polyvinyl chloride, polyvinylidene fluoride and Teflon (registered mark); natural rubber, neoplene rubber, nitryl rubber, Nodel, Viton rubber, Hypalon, polyurethane, Rayon (registered mark) and celluloses, at a thickness on the metal roller surface of not less than 0.5 mm, preferably 0.5-100 mm and specifically preferably 1.0-50 mm. A view point of selecting these materials for elastic body is not to be softened or eluted by an employed processing solution. Further, rubber hardness of elastic body 1 is measured by a method defined in JISK-6253 using Durometer A type, and is preferably 15-70 and more preferably 20-60.

In this invention, a static friction coefficient of the elastic body surface is preferably not less than 0.2 and not more than 0.9. It is more preferably not less than 0.3 and not more than 0.8. When it is not less than 0.2, an effect to correct wrinkles, uneven tension and distortion is large, and when it is not more than 0.9, rubbed long length roll-film is barely damaged, which are preferable.

A static friction coefficient of an elastic body can be measured by the following method.

(Static Friction Coefficient Measurement of Elastic Body)

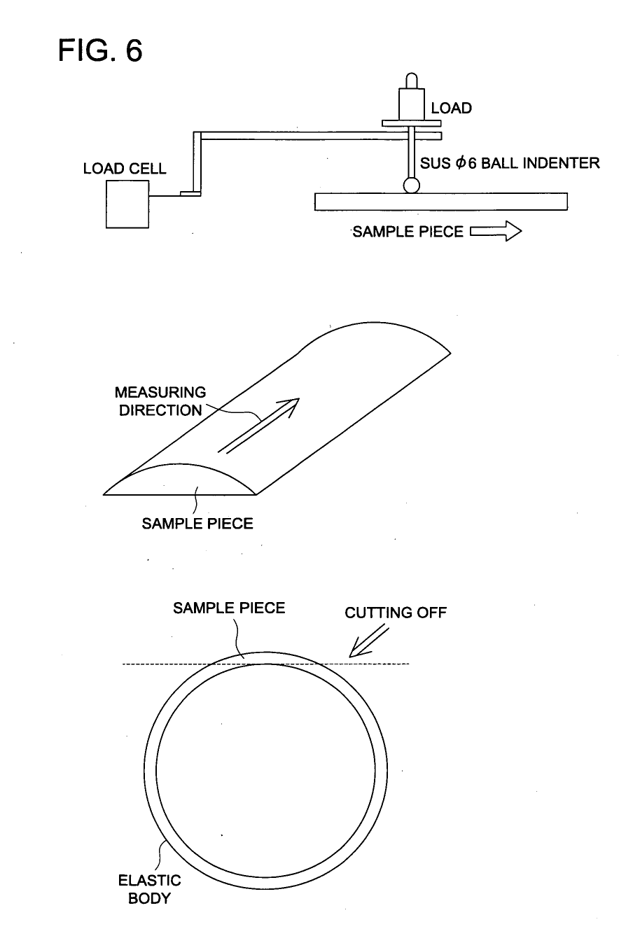

FIG. 6 shows an example of a method to measure a static friction coefficient of an elastic body utilized in this invention.

### (Ball Indenter Friction Test)

A friction coefficient of an object to be measured was measured by means of a ball indenter (SUS φ6) method by use of Heidon Surface Tester, Type: Heidon-14D (produced by Shinto Science Co., Ltd.). FIG. 6 is a principle drawing of this test.

In this Heidon surface tester, a weight for vertical load is attached on a ball made of SUS via a support member as shown in FIG. 6, and this SUS ball is pressed on a sample piece cut out from an elastic body with a weight of the weight for vertical load (200 g). Then, a friction force is measured when the aforesaid sample piece is transferred toward right facing to the paper.

Other measurement conditions with the tester will be shown below.

Measurement tool: Ball indenter (SUS, φ6)

Sample size: The sample size is not specifically limited; however, is preferably a size capable of assuring a transfer distance of not less than 50 mm.

Test load: 200 g (a weigh for vertical load)

Test speed: 600 mm/min

Atmosphere: 23±2° C., 50±10% RH (without dewing within an air conditioned range)

Elastic body 1 utilized in this invention is preferably made of surface modified rubber, and to make a static friction coefficient of elastic body 1 of the above-described range, it is preferable to employ a disclosed method such as a method to employ a silicone rubber layer filled with fluorine resin particles having been treated by a sodium-naphthalene complex, which is described in JP-A 7-158632; a method to employ a thin layer made of a fused body of ultra high molecular weight polyolefin powder, which is described in JP-A 9-85900; a method to form polycondensate of a hydrolysis product of alkoxysilane on vulcanized rubber, which is described in JP-A 11-166060; a method to perform a heating reaction of functional group containing monomer and rubber, which is described in JP-A 11-199691; a method to perform a reaction of rubber and silica, which is described in JP-A 2000-198864; a method to perform a heating reaction of a fluorine rubber substrate and functional group containing monomer, which is described in JP-A 2002-371151; a method to employ chloroprene type rubber which is described in JP-A 2004-251373; however, in this invention as described in JP-A 2000-158842, it is more preferable to employ a method in which rubber is utilized for an elastic body and adjusting the friction coefficient by the surface treatment with an organic halogen compound.

Rubber which can be modified by an organic halogen compound includes such as acrylonitrile•butadiene rubber, chloroprene rubber, styrene•butadiene rubber, synthetic isoprene rubber, polybutadiene rubber, ethylene•propyrene•diene three-dimensional polymer rubber and natural rubber. These rubbers are generally utilized by having been vulcanized, and vulcanization may be performed by a general vulcanization method utilized in the corresponding field.

As an organic halogenide treatment utilized for vulcanization of rubber described above, listed as examples are succinimide halogenide such as N-bromosuccinimide; hologenide compounds of cyanuric acid such as trichloroisocyanuric acid and dichloroisocyanuric acid; and hydantoin halogenide such as dichlorodimethyl hydantioin. Preferable is trichloroisocyanuric acid.

To make an organic halogen compound act on the rubber surface, it is preferable to be utilized at a suitable concentration by dissolving the compound in an organic solvent. A solvent suitable for this purpose is required not to react with an organic halogen compound, and includes aromatic hydrocarbons such as benzene and xylene; ethers such as diethylether, dioxane and tetrahydrofuran; esters such as ethylacetate; ketones such as methyl ethyl ketone and cyclohexanone; and hydrocarbon chlorides such as ethylchloride and chloroform. A concentration of an organic halogen compound in an organic solvent in the case of processing the rubber surface is not specifically limited, however, is generally 2-10 weight % and preferably 4-6 weight %. Efficiency to modify rubber is superior when the concentration is higher than 2 weight %, while uniform and effective coating is easy as well as the modification effect is sufficient and rubber is not hardened when the concentration is lower than 10 weight %.

To make a solution of an organic halogen compound act on rubber, it is possible by only bringing the both in contact without requiring no specific method, and for example, it is possible by spraying the solution or coating the solution by use of a brush on the rubber surface, or by immersing rubber in the solution and further with rubbing.

Further, a wrap angle of long length roll-film F against elastic body 1 is determined by arrangement of guide rollers 2 and 2′ which are arranged before and after elastic body 1. Since a processing time of long length roll-film F on elastic body 1 can be prolonged when a wrap angle is made large, higher effect of rubbing can be obtained, however, to perform stable conveyance without causing wrinkles, abrasion and weave, the wrap angle is set to less than 180 degree, preferably 1-135 degrees and more preferably 5-90 degrees. Further, a processing time can be prolonged by increasing a diameter of elastic body 1, however, the diameter is less than 200 cm, preferably 5-100 cm and furthermore preferably 10-50 cm, with respect to occupation area and cost.

Temperature of elastic body at the time of processing is preferably kept at not lower than 30° C. and not higher than 70° C. with respect to increasing efficiency of the processing.

A plane pressure loaded onto long length roll-film F on elastic body 1 can be controlled by air pressure from air nozzle 5 described before, however, is also determined by a tension and a roller diameter, in a film conveying system. Since a roller diameter is related with the above-described processing time, it is preferable to control a tension of a conveying system. To achieve an effect of this invention, it is preferred to maintain the plane pressure high; however, liquid film is broken to cause direct contact of elastic body 1 and long length roll-film F when the pressure is too high, resulting in easy generation of abrasion. Generally, the pressure is set to preferably not more than 9.8×10² Pa, more preferably 5×10-9.8×10² Pa, and further preferably 5×10-4.9×10² Pa.

Further, by adjusting a distance of air nozzle 6 from elastic body 1, it is preferable to control a wet time of long length roll-film surface to be processed with respect to prevention of such as water mark generation, and the wet time of the processing surface is preferably not shorter than 2 seconds and not longer than 60 seconds. The starting point of the wet time of long length roll-film surface to be processed is the start of processing by elastic body 1 without processing solution supply means (such as nozzle 8), which wets long length roll-film in advance, and is the time when long length roll-film surface to be processed become wet when a processing solution supply means (such as nozzle 8) is provided. The finish point of the wet time indicates the point when not less than 95% of liquid drops adhered on the surface to be processed of long length roll-film have been spattered or evaporated. Temperature of air ejected from air nozzle 6 is in a range of room temperature to 80° C. and more preferably 40-70° C.

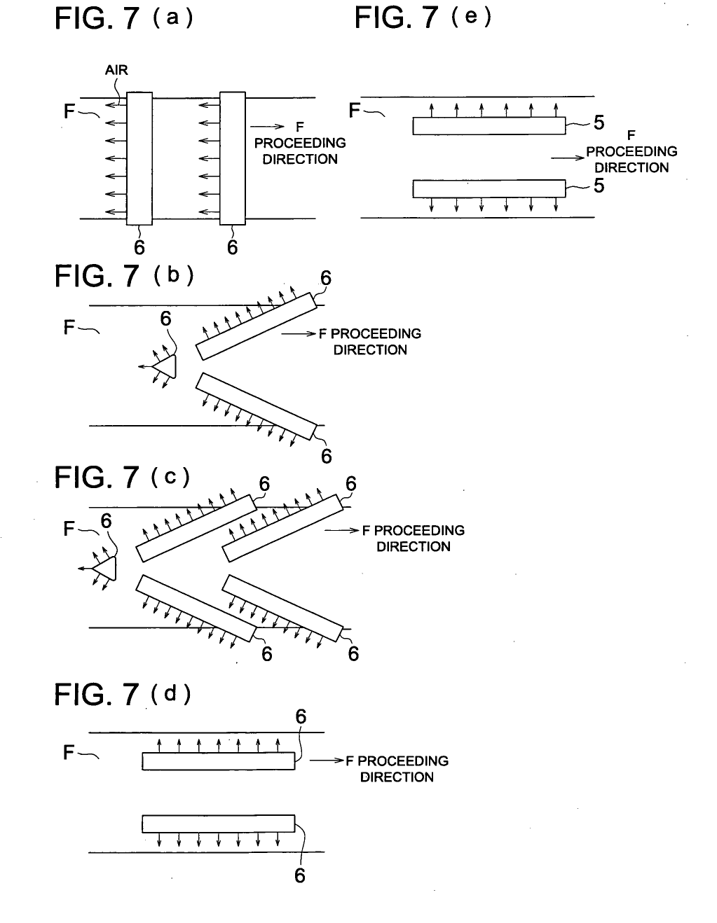

FIGS. 7 (a)-7 (e) are schematic drawings to show arrangement points of air nozzle 5 or 6 and the ejection direction of air. FIG. 7 (a) shows a state of air blowing counter-wise to the film proceeding direction, and FIGS. 7 (b) and (c) shows a state of air blowing toward the film outside. FIGS. 7 (d) and (e) are suitable particularly for air nozzle 5, which is arranged on the side opposite to the film surface to be processed, and exhibits a high effect to prevent over flow of processing solution to the back side.

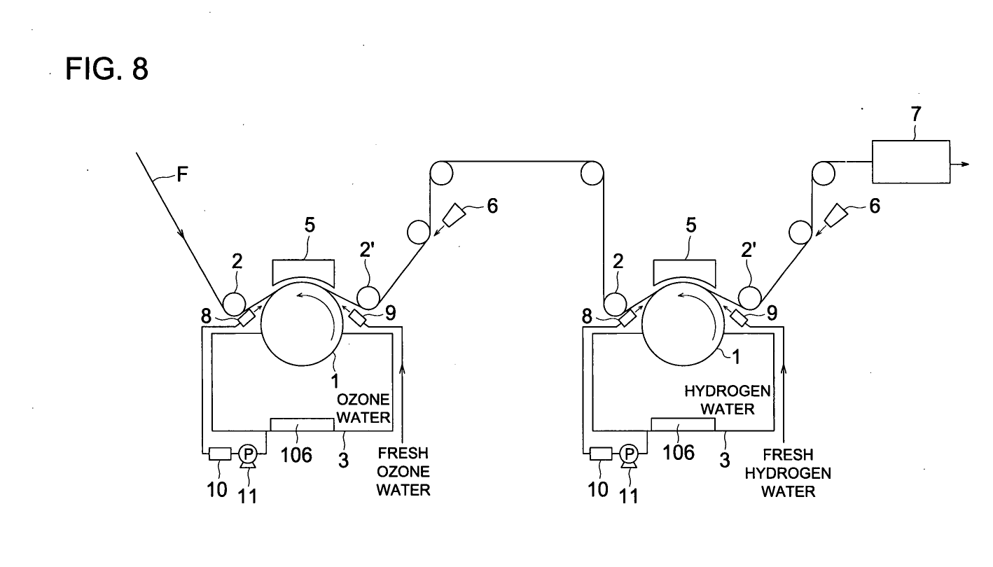

FIG. 8 shows another example of an apparatus of this invention, in which one surface of long length roll-film is rubbed by an elastic body being wetted with a processing solution. It is comprised of two sets of apparatuses described in FIG. 5 being coupled, the first set performs a treatment with ozone water and the other set can separately and continuously perform a similar treatment with hydrogen water.

FIG. 8, shows a state of processing solution supply means 8 in which a processing solution drawn out from processing solution tank 3 is conveyed by pump 11 through filter 10 and ejected, and processing solution supply means 9 in which a fresh liquid of a processing solution (being, for example, an ozone flesh solution), being supplied and ejected, however, possible is a constitution in which processing solution supply means 8 and 9 are reversed. In fresh liquid of a processing solution, ozone water dr hydrogen water supplied from an ozone water supply means or a hydrogen water supply means is contained.

Further, a filter utilized here can be appropriately selected, however, a filter having a pore size of 0.1-10 μm alone or an appropriate combination is utilized. Further, a pleats folding type cartridge filter can be advantageously selected with respect to filtering life and handling easiness. As for fresh liquid of a processing solution, filtered one is also preferably utilized.

Further, a filter circulation flow quantity is necessary to be set not as to increase a foreign matter number in a processing tank with aging due to foreign matters brought in from the film surface. To quantitative analysis of a foreign matter number in a processing solution, HIAC/ROYCO Liquid Micro-particle Counter Model 4100, manufactured by Nozaki Sangyo Co, Ltd. is conveniently utilized, and a separation size of a filter and a circulation flow quantity can be adjusted so that particles to be removed do not increase with operation time.

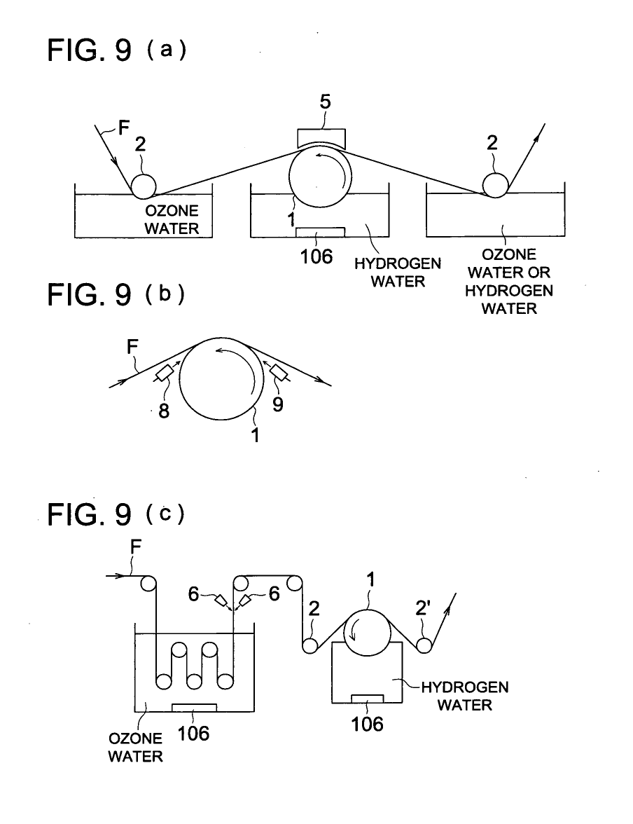

FIG. 9 is an example of another embodiment of an apparatus in which one surface of long length roll-film is rubbed. FIG. 9 (a) is an example of an immersion type, (b) is an example of ejection type and (c) is another example of an immersion type. These may be utilized in appropriate combination.

Further, in this invention, to precisely correct wrinkles, uneven tension and distortion, an apparatus to prevent meandering of long length roll-film is additionally arranged, and a meandering correction apparatus such as an edge position controller (also referred to as an EPC) and a center position controller (also referred to as a CPC), which is described in JP-A 6-8663, is preferably employed. In these apparatuses, a film edge is detected by an air servo sensor or an optical sensor to control the conveying direction based on information thereof so that the edge or the center in the width direction of the film, is kept at a constant position; and specifically, meandering is corrected by swinging one or two guide rollers or flat expander rollers, attached with a drive as the actuator, left and right (or up and down) against the line direction, or by arranging one set comprising two pinch rollers of a compact size on each left and right sides of the film (each one roller is arranged on the front and rear sides of film and the sets are on the both side of the film) and the film is pinched and pulled thereby to correct meandering (namely a cross-guider method). The principle of meandering correction of these apparatuses is that, for example, when film is going to left, roller is leaned to make film proceed to right in the former method and the film is pulled to right by being nipped with one set of pinch rollers on the right side in the latter method.

These meandering prevention apparatuses are preferably arranged in a range of 2-30 m on the upper stream side or the down stream side, starting from the position where an elastic body utilized in this invention is arranged, and at least one set is more preferably arranged each on the upper and down stream sides.

Optical film of this invention is characterized by being prepared via the above-described processing method, and optical film of this invention is preferably is antireflection film.

A preferable constitution of antireflection film of this invention is an accumulated body of optical interference layers comprising a high refractive index layer and a low refractive index layer in this order being accumulated on at least the one surface of a support (another layer may be appropriately added.). Further, it is preferable to provide a hard-coat layer between a support and an antireflection layer. A hard-coat layer is provided by employing the actinic ray curable resin described later.

In an antireflection layer, optical thickness of a high refractive index layer and a low refractive index layer is preferably set to λ/4 against wavelength λ. “Optical thickness” of this invention means a quantity defined by a product of refractive index “n” and layer thickness “d”. The height of a refractive index is almost determined by the metal or a compound contained therein, and, for example, Ti is high, Si is low and F-containing compound is further lower, whereby a refractive index is adjusted to the desired one by these combinations. A refractive index and a layer thickness are calculated based on measurement of spectral reflectance.

Herein, when a layer is prepared by coating a solution containing a metal compound on a support, the antireflection optical property is determined by physical layer thickness as described above.

Color of reflective light particularly near 550 nm changes between red purple and blue purple due to a slight difference as small as a few nm of a layer thickness. (This phenomenon is called as color unevenness.) This color unevenness is barely conspicuous in the case of transmitting light from a display being rich, however, is conspicuous in the case of small light quantity or a display is off, resulting in poor visual recognition. Further, when a difference of a layer thickness is large, it is hard to decrease reflectance at 400-700 nm, resulting in difficulty of obtaining desired antireflection characteristics.

### [Long Length Roll-Film]

Long length roll-film utilized in this invention is not specifically limited, however, listed are such as polyester film, cellulose ester film, polycarbonate film and cyclic olefin resin film. These are preferably utilized by being cast by a melt cast method or a solvent cast method. Among them, preferably utilized in this invention is cellulose ester film, specifically preferable is cellulose ester film having been stretched in one direction. As cellulose ester film, for example, Konica Minolta TAC KC8UX, KC4UX, KC5UX, KC8UY, KC4UY, KC12UR, KC8UCR-3, KC8UCR-4, KC8UCR-5 and KC8UX-H (produced by Konica Minolta Opto, Inc.) are preferably utilized. A layer thickness of long length roll-film is 10-500 μm and preferably 10-200 μm and the length is 100-10,000 m and preferably 300-5,000 m.

Long length roll-film having a free volume radius determined by a positron annihilation life method of 0.250-0.350 nm and preferably of 0250-0.310 nm is utilized.

A free volume referred here represents a vacant portion which is not occupied by cellulose resin molecular chain. This can be measured by means of a positron annihilation life method. Specifically, a time from ejection of positron into a sample until disappear of the positron is measured and information related to such as a size and a number concentration of an atom hole and a free volume is nondestructively observed based on the life thereof, whereby free volume radius can be determined.

### (Measurement of Free Volume Radius by Positron Annihilation Life Method)

Positron annihilation life and relative intensity were measured under the following measurement conditions.

### (Measurement Conditions)

Positron ray source: 22 NaCl (Intensity of 1.85 MBq)

Gamma ray detector: Plastic scitillator+photomultiplier

Apparatus time resolution: 290 ps

Measurement temperature: 23° C.

Total count number: 1,000,000 counts

Sample size: 20 sheets of slices having a size of 20 mm×15 mm were stacked to make a thickness of approximately 2 mm. Samples were subjected to vacuum drying for 24 hours before measurement.

Irradiation area: approximately 10 mmφ

Time per one channel: 23.3 ps/ch

A positron annihilation life measurement was performed under the above-described measurement conditions and three component analysis based on a non-linear least square method was performed, whereby annihilation life was defined as τ1, τ2, and τ3, from the shortest, and corresponding intensities as I1, I2 and I3 (I1+I2+I3=100%). Free volume radius R3 (nm) was determined from the longest mean annihilation life τ3, according to the following equation. τ3 corresponds to positron annihilation in a hole and the larger is τ3, it is considered that the larger is hole size.

τ3=(½)[1-{R3/(R3+0.166)}+(½π) sin {2πR3/(R3+0.166)}]−1

wherein, 0.166 (nm) corresponds to thickness of an electron layer extruded from the hole wall.

Twice of the above measurement were repeated and the average was determined.

With respect to a positron annihilation method, for example, “Evaluation of Free volume of Polymer by Positron Annihilation Method” is published in Material Stage vol. 4, No. 5, pp. 21-25 (2004), The TRC News No. 80 pp. 20-22 (July 2003) published by Toray Research Center, and “Bunseki pp. 11-20 (1988)”, which can be referred to.

A free volume radius of long length roll-film of this invention is preferably 0.250-0.310 nm and more preferably 0.270-0.305 nm.

A method to adjust a free volume radius of long length roll-film into a predetermined range is not specifically limited; however, it can be controlled by the following method.

Long length roll-film having a free volume radius, which is determined by a positron annihilation life method, of 0.250-0.310 nm can be prepared as follows; a web is prepared by casting a dope containing cellulose ester described later and at least a plastisizer, and dried until the residual solvent amount reaches less then 0.3%, after having been stretched while containing a solvent, to prepare cellulose ester film, then this is further treated while being conveyed at 105-155° C. under an atmosphere substitution rate of not less than 12 times/hour and preferably of 12-45 times/hour, whereby long length roll-film having a predetermined free volume radius can be prepared.

An atmosphere substitution rate is a number of times per unit time to substitute the atmosphere of a thermal treatment room by fresh air which is determined by the following equation, when an atmosphere volume of a thermal treatment room is V (m²) and a blowing wind amount of fresh air is FA (m³/hr). Fresh air means not a wind being utilized by recycling but a fresh wind which contains no evaporated solvent and a plastisizer, or from which they have been eliminated.

Atmosphere substitution rate=FA/V (times/hour)

Temperature of treatment is preferably 105-155° C. and more preferably 110-150° C. Further, it is preferable to perform a treatment in an atmosphere kept at an atmosphere substitution rate in the treatment portion of not less than 12 times/hour.

Further, in this treatment process, a free volume radius can be controlled into more preferable range by pressing the film in the thickness direction. A preferable pressure is 0.5−10 kPa. A residual solvent amount is preferably less than 0.3% at the time of pressing with respect to an effect of such as flatness improvement.

As cellulose as a raw material of cellulose ester preferably utilized in this invention is not specifically limited, however, includes such as cotton linter, wood pulp and kenaf. Cellulose ester prepared from them can be utilized each alone or in combination at an arbitrary ratio, however, it is preferable to use not less than 50 weight % of cotton linter.

In the case of an acylation agent of cellulose raw material being acid anhydride (such as acetic acid anhydride, propionic acid anhydride and butyric acid anhydride), a reaction to prepare cellulose ester is performed by employing an organic acid such as acetic acid or an organic solvent such as methylene chloride and a proton catalyst such as sulfuric acid. In the case of an acylation agent being acid chloride (such as CH₃COCl, C₂H₅COCl and C₃H₇COCl), the reaction is performed by employing a basic compound such as amine as a catalyst. Specifically, cellulose ester is synthesized by a method described in JP-A 10-45804. In cellulose ester, an acyl group reacts with a hydroxyl group of a cellulose molecule. A cellulose molecule is comprised of many glucose units are bonded each other, and a glucose unit has three hydroxyl groups. The number of acyl groups, which are introduced to these three hydroxyl groups, is referred as a substitution degree.

For example, in cellulose triacetate, acetyl groups bond to all three hydroxyl groups of a glucose unit.

Cellulose ester utilizable for cellulose ester film is not specifically limited, however, a substitution degree of the total acyl group is preferably 2.40-2.98 and it is more preferable that a substitution degree of an acetyl group among the acyl groups is not less than 1.4.

A substitution degree of an acyl group can be measured based on a measurement method of ASTM-D817-96.

Cellulose ester is preferably cellulose acetate such as cellulose triacetate or cellulose diacetate; or cellulose ester, to which a propionate group or a butylate group other than an acetyl group is bonded, such as cellulose acetate propionate or cellulose acetate propionate butylate. Herein, butyrate includes iso- in adition to n-. Cellulose acetate propionate having a large substitution degree of a propionate group is excellent in water resistance.

A number average molecular weight Mn of cellulose ester is preferably in a range of 70,000-250,000, with respect to high mechanical strength of prepared film and a suitable dope viscosity. More preferable is a range of 80,000-150,000. Further, cellulose ester having a ratio of a weight average molecular weight Mw thereto (Mw/Mn) of 1.0-5.0 is preferably utilized. Furthermore preferable is 1.5-4.5.

### <Measurement of Number Average Molecular Weight>

It is measured by means of high speed liquid chromatography under the following condition.

Solvent: acetone

Column: MPW×1 (produced by Toso Co., Ltd.)

Sample concentration: 0.2 (weight/volume) %

Flow rate: 1.0 ml/min

Sample injection quantity: 300

Standard sample: Polymethylmethacrylate (weight average molecular weight of 188, 200)

Temperature: 23° C.

Further, the amount of a metal which is used during cellulose ester production or mixed in used materials even at a trace amount is preferably as small as possible, and the total amount of metal such as Ca, Mg, Fe and Na is preferably not more than 100 ppm.

### [Organic Solvent]

A useful solvent to prepare a cellulose ester solution or dope in which cellulose ester is dissolved includes methylene chloride (chloromethylene) as a chlorine type organic solvent, which is suitable for dissolution of cellulose ester, specifically, of cellulose triacetate. A non-chlorine type organic solvent includes such as methyl formate, ethyl acetate, amyl acetate, acetone, tetrahydrofuran, 1,3-dioxane, 1,4-dioxane, cyclohexanone, ethyl formate, 2,2,2-trifluoroethanol, 2,2,3,3-tetrafluoro-1-propanol, 1,3-difluoro-2-propanol, 1,1,1,3,3,3-hexafluoro-2-methyl-2-propanol, 1,1,1,3,3,3-hexafluoro-2-propanol, 2,2,3,3,3-pentafluoro-1-propanol and nitroethane.

In the case of utilizing these organic solvents for cellulose triacetate, it is possible to employ a dissolution method at ordinary temperature; however, it is preferable to employ a dissolution method such as a high temperature dissolution method, a cooled dissolution method and a high pressure dissolution method because of capability to reduce insoluble substances.

For cellulose ester other than cellulose triacetate, methylene chloride can be also utilized; however, methyl acetate, ethyl acetate and acetone can be preferably utilized without employing methylene chloride. Specifically preferable is methyl acetate. In this invention, an organic solvent having good solubility against the above-described cellulose ester is called as a good solvent, and an organic solvent which exhibits primary effect for dissolution and utilized at a large amount for dissolution is called a primary (organic) solvent or a main (organic) solvent.

In a dope, it is preferable to blend 1-40 weight % of alcohol having a carbon number of 1-4 other than organic solvents described above. These are utilized as a gelation solvent, which enables easy peel off of a web from a metal support by strengthening the web when solvents start to evaporate after casting of a dope on a metal support to increase a ratio of alcohol resulting in gelation of a web; or have a role to accelerate dissolution of cellulose ester by non-chlorine type organic solvent when a ratio thereof is small.

Alcohol having a carbon number of 1-4 includes methanol, ethanol, n-propanol, iso-propanol, n-butanol, sec-butanol and Cert-butanol.

Among them preferable is ethanol with respect to excellent stability of a dope, a relatively low boiling point and a good drying ability. These organic solvents have no dissolving power against cellulose ester and are called as a poor solvent.

### [Preparation of Cellulose Ester Film by Solution Casting Method]

A casting method of cellulose ester film which is utilized as a support will be now explained. Cellulose ester film is prepared by a solution casting method.

(1) Dissolution Process: This is a process in which cellulose ester, polymer and an additive are dissolved into an organic solvent primarily comprising a good solvent for the cellulose ester (in a flake form) in a dissolution vessel while being stirred to form a dope, or a process in which a polymer solution and an additive solution are mixed with a cellulose ester solution to form a dope. To dissolve cellulose ester, dissolution methods such as a method performed at ordinary pressure, a method performed at not higher than a boiling point of a primary solvent, a method performed under pressure at not lower than a boiling point of a primary solvent, a method performed by means of a cooling dissolution method as described in JP-A No. 9-95544, 9-95557 or 9-95538, and a method performed under a high pressure as described in JP-A 11-21379, can be employed, however, in this invention, a method performed under pressure at not lower than a boiling point of a primary solvent is preferred.

A concentration of cellulose ester in a dope is preferably 10-35 weight %. A dope, during or after dissolution, added with an additive to be dissolved and dispersed, followed by being filtered and defoamed, and the resulting dope is sent to the following process by a solution sending pump.

(2) Casting Process: This is a process in which a dope is sent to a pressure die through a solution sending pump (such as a pressure type metering gear pump), and a dope is cast at a casting position on a metal support, such as an endlessly conveying edgeless metal belt, for example comprising a stainless belt, or a rotating metal drum, from a pressure die slit. Preferably utilized is a pressure die which is easy to make a uniform film thickness by adjusting a slit shape of an outlet portion of a die. A pressure die includes such as a coat hanger die and a T die, and either one can be preferably utilized. The metal surface makes a mirror surface. To increase a casting rate, at least two sets of pressure dies may be arranged on a metal support to multi-coat a dope by dividing the dope amount.

(3) Solvent Evaporation Process: This is a process in which a web is heated on a metal support to evaporate a solvent until making the web peelable from a metal support. To evaporate a solvent, employed can be such as a method to blow wind from a web side and/or a method to transmit heat with a liquid from the rear surface of a metal support, and a method to transmit heat from front and rear surfaces with radiant heat; however, a method of rear surface liquid heat transmission is preferable with respect to a drying efficiency. Further, combinations thereof are also preferable. In the case of rear surface liquid heat transmission, it is preferable to heat a web at not higher than a boiling point of a primary solvent or of an organic solvent having the lowest boiling point, among organic solvents utilized in a dope.

(4) Peeling Process: This is a process in which a web, solvent of which having been evaporated, on a metal support is peeled off at a peeling position. A peeled web is sent to the next process. Peeling may be difficult when a residual solvent amount (shown by the following equation) of a web is too large at the time of peeling off, while a part of a web may be peeled off on the way when a web is peeled off after having been sufficiently dried on a metal support.

A method to increase a casting speed (a casting speed can be increased because of peeling while an amount of a residual solvent is as large as possible) includes a gel casting method (gel casting).

In a drying method and a production method of optical film according to this invention, when cellulose ester film prepared by a solution casting method is utilized as a support, a solution casting method itself is not specifically limited, and can be referred to methods commonly utilized in the art, such as methods described in U.S. Pat. Nos. 2,492,978, 2,739,070, 2,739,069, 2,492,977, 2,336,310, 2,367,603 and 2,607,704; BP Nos. 64,071 and 735,892; Examined Japanese Patent Application Publication Nos. 45-9074, 49-4554, 49-5614, 60-27562, 61-39890 and 62-4208.

Solvents utilized for preparation of a dope of cellulose ester employed in a solution casting method may be utilized alone or in combination of at least two types, however, a good solvent and a poor solvent for cellulose ester being mixed are preferably utilized with respect to production efficiency, and further, the more amount of a good solvent is preferably employed with respect to solubility of cellulose ester. A preferable range of a mixing ratio of a good solvent and a poor solvent is 70-98 weight % for a good solvent and 30-2 weight % for a poor solvent.

“A good solvent” and “a poor solvent” are defined as follows: a good solvent independently dissolves cellulose ester and a poor solvent swells or does not independently dissolve cellulose ester. Therefore, a good solvent and a poor solvent differ depending on a mean saponification degree of cellulose ester, and, for example, in the case of utilizing acetone as a solvent, it is a good solvent at a bonded acetic acid amount of cellulose of 55% while it is a poor solvent at a bonded acetic acid amount of cellulose of 60%.

A good solvent utilized in this invention is not specifically limited, however, preferably includes organic halogen compounds such as methylene chloride; dioxolanes; and methyl acetate, in the case of cellulose triacetate; and further, such as methylene chloride, acetone, and methyl acetate, in the case of cellulose acetate propionate.

Further, a poor solvent utilized in this invention is not specifically limited, however, preferably includes methanol, ethanol, i-propanol, n-butanol, cycloheane, acetone and cyclohexanone.

As a dissolution method of cellulose ester at the time of preparation of the above-described dope solution, a general method can be utilized, however, a method in which dissolution is carried out while stirring under pressure and heating at a temperature in a range of not lower than a boiling point at a ordinary pressure of a solvent and not to boil the solvent, is preferable, because it can prevent generation of bulk insoluble materials called as gel or undissolved lumps.

Further, preferably utilized is a method in which cellulose ester, after having been mixed with a poor solvent to be wetted or swelled, is dissolved further mixing with a good solvent.

A type of a pressure vessel is not specifically limited and utilized are those provided being durable to a predetermined pressure and enabling to heat and mix under pressure. In a pressure vessel, in addition to these, measuring instruments such as a manometer and a thermometer are appropriately arranged. Pressure may be applied by a method of injecting an inert gas such as a nitrogen gas with pressure, or by increasing vapor pressure of a solvent by heating. Heating is preferably supplied from outside, and a jacket type is preferable with respect to easy temperature control.

Heating temperature with addition of a solvent is preferably performed at not lower than a boiling point of a utilized solvent under ordinary pressure and in a range of not to boil the solvent, with respect to solubility of cellulose ester, however, excessively high heating temperature requires higher pressure resulting in a poor production efficiency. Preferable heating temperature is in a range of 45-120° C., more preferably of 60-11° C. and furthermore preferably of 70-105° C. Further, pressure is adjusted not to boil a solvent at a set temperature.

An additive such as a plastisizer and an ultraviolet absorber, which is necessary other than cellulose ester and a solvent, may be charged into a solvent before dissolution of cellulose ester by having being mixed with a solvent to be dissolved or dispersed in advance, or may be charged into a dope after dissolution of cellulose ester.

After dissolution, a dope is taken out from a vessel while cooling, or extracted from a vessel by use of such as a pump followed by being cooled with such as a heat exchanger, and then the dope is supplied for casting, and a cooling temperature at this time may be an ordinary temperature, however, it is preferable to cool the dope down to a temperature of lower than a boiling point by 5-10° C. and casting is performed keeping the temperature as it is, because of a lower dope viscosity.

A measurement method of a substitution degree of an acyl group can be performed based on a definition of ASTM-817-96.

This cellulose ester is generally produced (cast) by a method called as a solution casting method as described later. In this method, production is performed by casting a dope on a metal support for casting such as an infinitely conveyed endless metal belt (for example, a stainless steel belt) or a rotating metal drum (for example, a drum made of cast ion and being plated with chromium), peeling off a web (a dope film) on a metal support from the metal support and drying the web.

In this invention, a layer thickness of cellulose ester film is preferably 30-200 μm and specifically preferably 30-70 μm. Heretofore, such thin film is liable to suffer from coating unevenness; however, this invention enables stable coating behavior even with thin film having a thickness of not more than 70 μm.

In this invention, when an optical thin layer is provided on a support surface as described above, it is possible to provide a thin layer having a layer thickness deviation against a mean layer thickness of ±8%, more preferably within ±5% and specifically preferably within ±1%. A production method of this invention particularly exhibits a significant effect when being applied for optical film having a width of as wide as not less than 1.4 m. The upper limit of an optical film width preferably applied is not specifically limited with respect to layer thickness precision, however, is preferably not more than 4 m with respect to a manufacturing cost.

Optical film according to this invention can be provided with easy operation of conveyance and winding by incorporating a matting agent in cellulose ester film.

A matting agent is preferably those having a minute particle size as possible and micro-particles include inorganic micro-particles such as silicon dioxide, titanium dioxide, aluminum oxide, zirconium oxide, calcium carbonate, kaolin, talc, burned calcium silicate, calcium silicate hydrate, aluminum silicate, magnesium silicate and calcium phosphate; polymethacrylic methylacrylate resin powder, acryl styrene type resin powder, polymethyl methacrylate resin powder, silicone type resin powder, polystyrene type resin powder, polycarbonate resin powder, benzoguanamine type resin powder, melamine type resin powder, polyolefin type resin powder, polyester type resin powder, polyamide type resin powder, polyimide type resin powder or polyfluoroethylene type resin powder, however, specifically preferable are cross-linked polymer micro-particles. This invention is not limited thereto.

Among those described above, silicon dioxide is specifically preferable to adjust a dynamic friction coefficient, in addition to minimizing a haze of film. A primary particle size or a secondary particle size of micro-particles is in a range of 0.01-5.0 μm and preferably of 0.01-1.0 μm, and the content is preferably 0.005-0.5 weight % based on cellulose ester.

Micro-particles such as silicon dioxide have been often surface treated with an organic compound, and such micro-particles are preferable because of enabling decrease of film haze.

An organic substance preferable in a surface treatment includes halosilanes, alkoxy silanes, silazane and siloxane. The larger is a mean particle size of micro-particles, the larger is a sliding property effect, while on the other hand, the smaller is a mean particle size, the more superior is transparency. Therefore, a preferable mean primary particle size of micro-particles is not more than 20 nm, preferably 5-16 nm and specifically preferably 5-12 nm.

These micro-particles in cellulose ester film preferably form roughness having a height of 0.01-1.0 μm on the cellulose ester film surface.

Silicon dioxide micro-particles include Aerosil 200, 200V, 300, R972, R972V, R974, R202, R812, OX50 and TT600, produced by Nippon Aerosil Co., Ltd., and preferable are Aerosil 200V, R972, R972V, R974, R202 and R812. These micro-particles may be utilized in combination of at least two types. Micro-particles, when utilized by mixing at least two types, can be utilized by mixing at an arbitrary ratio. In this case, micro-particles having different mean particle size and comprising different materials, such as Aerosil 200V and R972, can be utilized at a weight ratio range of 0.1/99.9-99.9/0.1. As zirconium oxide, a product available on the market such as Aerosil R976 or R811 (produced by Nippon Aerosil Co., Ltd.) can be also utilized.

As organic micro-particles, a product available on the market such as Tosparl 103, 105, 108, 120, 145, 3120 and 240 as silicone resin (produced by Toshiba Silicones Co., Ltd.) can be also utilized.

Measurement of a primary particle size of micro-particles preferably utilized in this invention was performed by observing particles through a transparent type electronmicroscope (at a magnification of 500,000-2,000,000 times), with respect to 100 particles, and an average value thereof is defined as a mean primary particle size.

An apparent specific gravity is preferably not less than 70 g/liter, more preferably 90-200 g/liter and specifically preferably 100-200 g/liter. The larger is an apparent specific gravity, possible is preparation of dispersion having the high concentration, resulting in improvement of haze and prevention of aggregation, which is preferred; further this is applied particularly for preparation of a dope having a high solid concentration as in this invention.

Silicon dioxide micro-particles having a mean primary particle size of not more than 20 nm and an apparent specific gravity of not less than 70 g/liter can be prepared, for example, by vaporized silicon tetrachloride being mixed with hydrogen to be burned in air at 1000-1200° C. In this invention, the above-described apparent specific gravity was determined by sampling a predetermined amount of silicon dioxide micro-particles was messed by a mess-cylinder to be weighed and by calculation according to the following equation.

Apparent specific gravity (g/L)=weight of silicon dioxide (g)/volume of silicon dioxide (L)

A method to prepare dispersion of micro-particles useful for this invention and to add the dispersion into a dope includes three methods shown below.

### <Preparation Method A>

Organic solvent and micro-particles, after having been mixed with stirring, were dispersed by use of a homogenizer. The resulting dispersion is designated as micro-particle dispersion. The micro-particle dispersion is added into a dope and stirred.

### <Preparation Method B>

An organic solvent and micro-particles after having been mixed with stirring are dispersed by use of a homogenizer. This is designated as micro-particle dispersion. Separately, the micro-particle dispersion is added into a solution, in which a small amount of cellulose ester is added and dissolved in an organic solvent, and is stirred. This is designated as a micro-particle additive solution and is sufficiently mixed with a dope solution by use of an inline mixer. Herein, an ultraviolet absorbent may be added after micro-particle additive solution described below has been added.

### <Preparation Method C>

A small amount of cellulose ester is added in an organic solvent and stirred to be dissolved. Micro-particles are added therein and dispersed by use of a homogenizer.

This is designated as micro-particle additive solution. The micro-particle additive solution is sufficiently mixed with a dope solution by use of an inline mixer.

Preparation method A is superior in dispersibility of silicon dioxide micro-particles and preparation method C is superior in minimum re-aggregation of silicon dioxide micro-particles. Among them, preparation method B described above is a preferable one which is superior in both of dispersibility of silicon dioxide micro-particles as well as minimum re-aggregation of silicon dioxide micro-particles.

### <Dispersion Method>

A concentration of silicon dioxide at the time of silicon dioxide micro-particles being mixed with an organic solvent and dispersed is preferably 5-30 weight %, more preferably 10-25 weight and most preferably 15-20 weight %.

An addition amount of silicon dioxide micro-particles against cellulose ester is preferably 0.01-0.5 weight parts, more preferably 0.05-0.2 weight parts and most preferably 0.08-0.12 weight parts, against 100 weight parts of cellulose ester. The larger is the addition amount, the more superior is a dynamic friction coefficient of cellulose ester film, while, the smaller is the addition amount, the more superior are decreasing haze and minimum re-aggregation.

An organic solvent utilized for dispersion is preferably lower alcohols, and lower alcohols include such methanol, ethanol, propyl alcohol, isopropyl alcohol and butanol, which can be preferably utilized. An organic solvent utilized other than lower alcohols are not specifically limited; however, organic solvents utilized at the time of preparation of a dope are preferable.

As a homogenizer, various types of homogenizers, well-known in the art, can be employed. Homogenizers are roughly classified into a medium homogenizer and a medium-less homogenizer. For dispersion of silicon dioxide micro-particles, the latter is preferred due to lower haze. A medium-less homogenizer includes such as a ball mill, a sand mill and die mill. Further, a medium-less homogenizer includes an ultra sonic type, a centrifugal type and a high pressure type, however, a high pressure type is preferable in this invention. A high pressure homogenizer is an apparatus to provide a condition of a high share or high pressure state by passing a composition, comprising micro-particles and an organic solvent having been mixed, through a micro tube at a high speed. In a process by a high pressure homogenizer, for example, it is preferably performed under the maximum pressure condition of not less than 9.8 MPa in a micro tube having a tube diameter of 1-2,000 μm. More preferable is 19.8 Mpa. Further, at that time, it is preferable that the maximum speed reaches not less than 100 m/sec and a heat conduction rate reaches not less than 420 kJ/hour.

A high pressure homogenizer as described above includes an ultra-high pressure homogenizer (product name: Microfluidizer) produced by Microfluidics Corporation or Nanomizer produced by Nanomizer Corp., in addition to a Manton-Gaulin type high pressure homogenizer such as a homogenizer produced by Izumi Food Machinery Co., Ltd. and UHN-01 produced by Sanwa Machine Co., Inc.

In this invention, at the time of the above described micro-particles being incorporated, the micro-particles are preferably distributed uniformly in the thickness direction, however, more preferably distributed so as to primarily exist at the surface neighborhood, and for example, it is preferable that two types of dopes are simultaneously cast by a co-casting method employing one die so that a dope containing micro-particles is arranged on the surface side. In this manner, haze can be decreased as well as a dynamic friction coefficient can be lowered. It is furthermore preferable that by utilizing three types of dopes to arrange dopes containing micro-particles in one layer or both layers on the front layer side.

To adjust a dynamic friction coefficient of a support, a back-coat layer containing micro-particles may be also provided on the rear side. The dynamic friction coefficient can be adjusted by changing a size, an addition amount and a material of micro-particles.

As a plastisizer utilized in this invention, phosphoric ester type plastisizers and non-phosphoric ester type plastisizers are preferably employed.

A phosphoric ester type plastisizer includes such as triphenyl phosphate, tricresyl phosphate, cresyldiphenyl phosphate, octyldiphenyl phosphate, diphenylbiphenyl phosphate, trioctyl phosphate and tributyl phosphate.

A non-phosphoric ester type plastisizer includes such as phthalic ester, polyhydric alcohol ester, polycarboxylic ester, citric ester, glycolic ester, fatty acid ester, pyromellitic ester, trimellitic ester and polyester.

Among them preferable are such as a polyhydric alcohol ester type, plastisizer, phthalic ester, citric ester, fatty acid ester, a glycolate type plastisizer and a polyester type plastisizer.

A polyhydric alcohol ester type plastisizer is comprised of ester of fatty acid polyhydric alcohol having at least divalency and monocarboxylic acid, and it is preferably provided with an aromatic or cycloalkyl ring in a molecule. Preferable is a fatty acid polyhydric alcohol ester having 2-20 valency.

Polyhydric alcohol utilized in this invention is represented by following general formula (1).

R₁—(OH)ₙ Formula (1)

wherein, R₁ is a n-valent organic group, n is an integer of at least 2, and OH group is an alcoholic and/or phenolic hydroxyl group.

Examples of preferable polyhydric alcohol include the followings; however, this invention is not limited thereto. Preferably listed are such as adonitol, arabitol, ethylene glycol, diethylene glycol, triethylene glycol, tetraethylene glycol, 1,2-propanediol, 1,3-propanediol, dipropylene glycol, tripropylene glycol, 1,2-butanediol, 1,3-butanediol, 1,4-butanediol, dibutylene glycol, 1,2,4-butanetriol, 1,5-pentanediol, 1,6-hexanediol, hexanetriol, galactitol, mannitol, 3-methylpentane-1,3,5-triol, pinacol, sorbitol, trimethylol propane, trimethylol ethane and xylitol. Specifically preferable are triethylene glycol, tetraethylene glycol, dipropylene glycol, tripropylene glycol, sorbitol, trimethylol propane and xylitol.

Carboxylic acid utilized in polyhydric alcohol ester of this invention is not specifically limited and such as commonly known aliphatic monocarboxylic acid, alicyclic monocarboxylic acid, aromatic monocarboxylic acid can be utilized. Alicyclic monocarboxylic acid and aromatic monocarboxylic acid are preferably employed with respect to improvement of moisture permeability and retention.

Examples of preferable monocarboxylic acid include the following; however, this invention is not limited thereto.

As aliphatic monocarboxylic acid, aliphatic acid provided with a straight chain or a side chain having a carbon number of 1-32 can be preferably utilized. The carbon number is more preferably 1-20 and specifically preferably 1-10. It is preferred to incorporate acetic acid because compatibility with cellulose ester is increased, and it is also preferable to utilize acetic acid and other monocarboxylic acid in combination.

Preferable aliphatic monocarboxylic acid includes saturated fatty acid such as acetic acid, propionic acid, butylic acid, valeric acid, capronic acid, enanthic acid, caprylic acid, pelargonic acid, caprinic acid, 2-ethyl-hexanic acid, undecylic acid, lauric acid, tridecylic acid, myristic acid, pentadecylic acid, palmitic acid, heptadecylic acid, stearic acid, nonadecanoic acid, arachic acid, behenic acid, lignoceric acid, cerotic acid, heptacosanic acid, montanic acid, mellissic acid and lacceric acid; and unsaturated fatty acid such as undecylenic acid, oleic acid, sorbic acid, linoleic acid, linolenic acid and arachidonic acid.

Examples of preferable alicyclic monocarboxylic acid include cyclopentane carboxylic acid, cyclohexane carboxylic acid, cyclooctane carboxylic acid and derivatives thereof.

Examples of preferable aromatic monocarboxylic acid include those, in which an alkyl group is introduced in a benzene ring of benzoic acid, such as benzoic acid and toluic acid; and aromatic monocarboxylic acid provided with at least two benzene rings such as biphenyl carboxylic acid, naphthalene carboxylic acid and tetralin carboxylic acid. Specifically preferable is benzoic acid.

A molecular weight of polyhydric alcohol ester is not specifically limited, however, is preferably 300-1,500 and more preferably 350-750. Since volatility decreases with increase of the molecular weight, the molecular weigh is preferably the smaller with respect to moisture permeability and compatibility with cellulose ester.

Carboxylic acid utilized in polyhydric alcohol ester may be either one type or a mixture of at least two types. Further, OH groups in polyhydric alcohol may be all esterified or partly remain as an OH group.

In the following, specific examples of polyhydric alcohol ester will be shown.

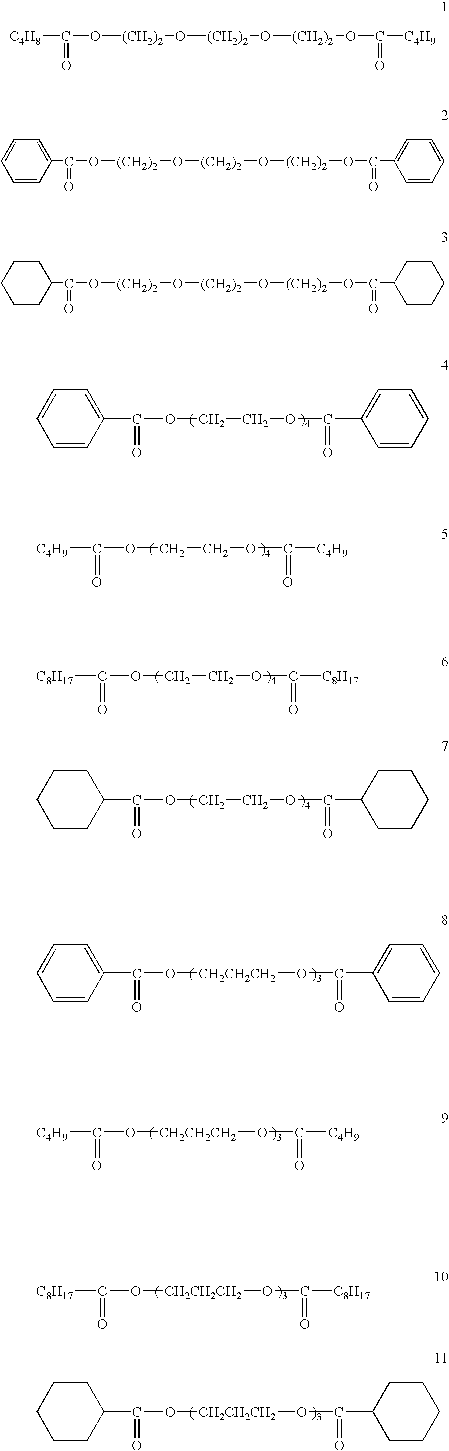

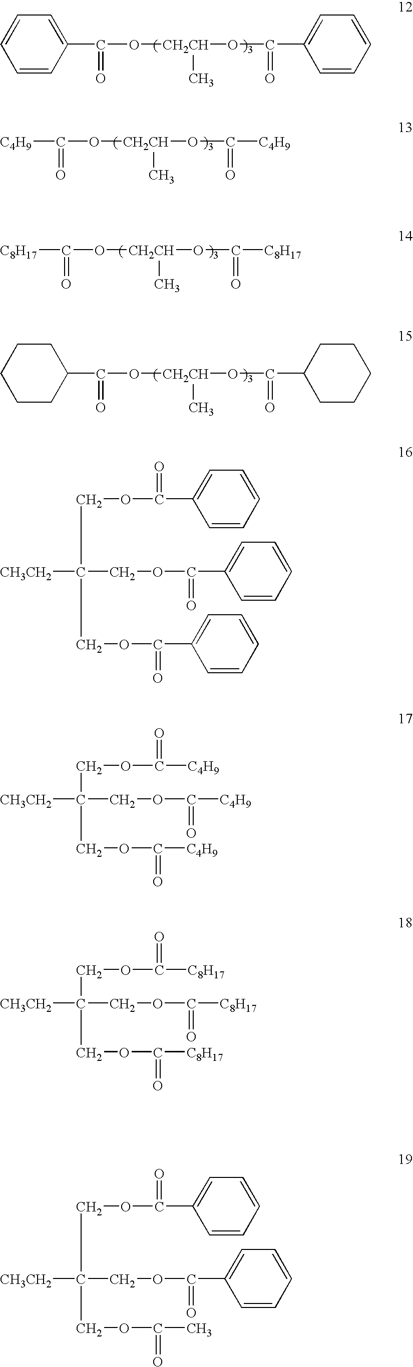

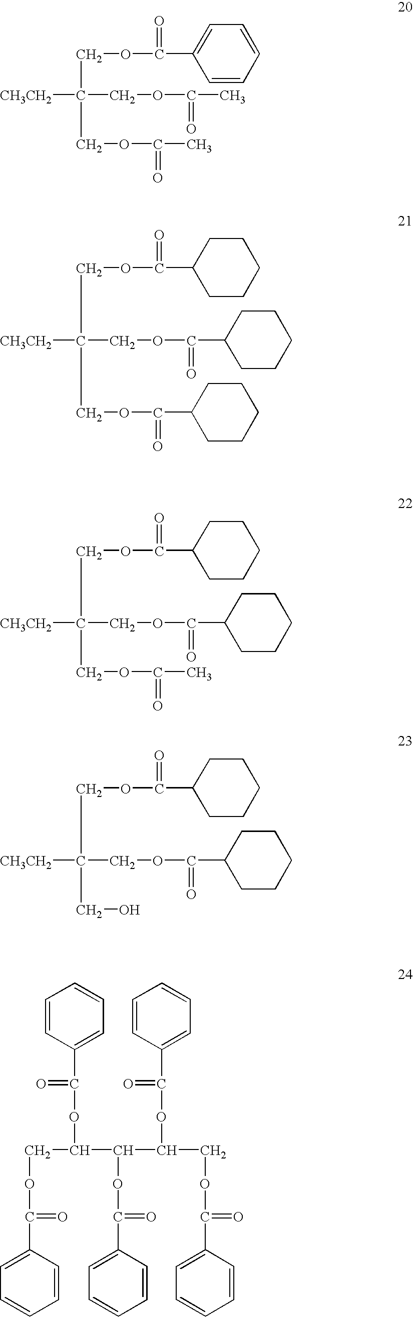

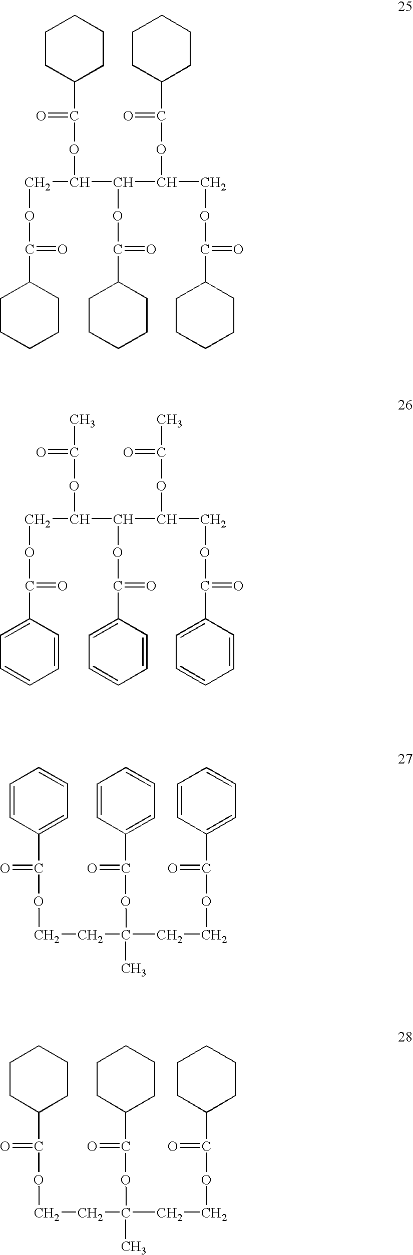

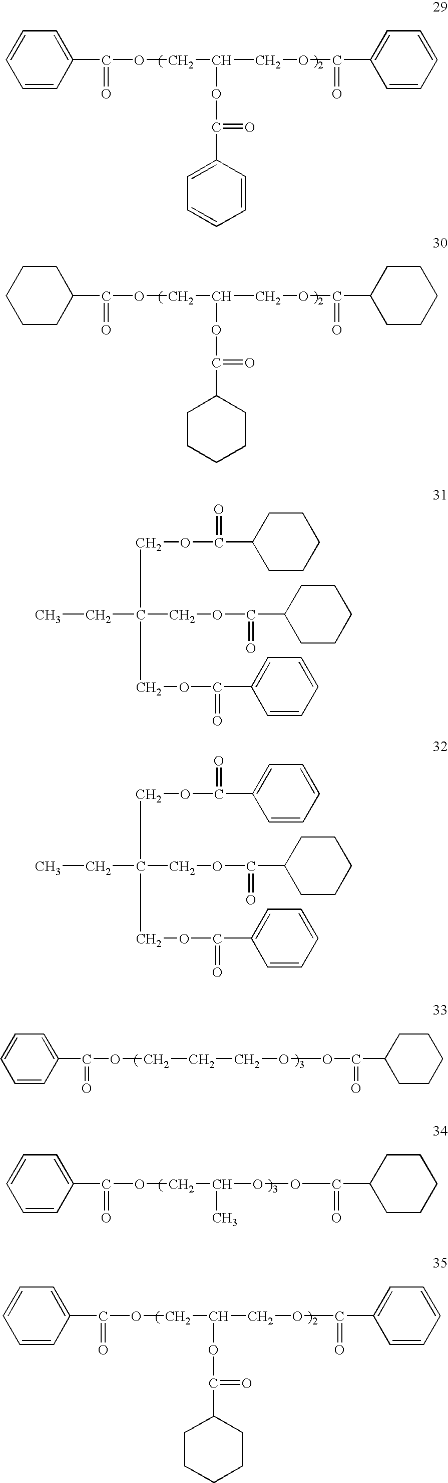

A glycolate type plastisizer is not specifically limited; however alkylphthalyl alkylglycolate can be preferably utilized. Alkylphthalyl alkylglycolates include such as methylphthalyl methylglycolate, ethylphthalyl ethylglycolate, propylphthalyl propylglycolate, octylphthalyl octyiglycolate, methylphthalyl ethylglycolate, ethylphthalyl methylglycolate, ethylphthalyl propylglycolate, methylphthalyl butylglycolate, ethylphthalyl butylglycolate, butylphthalyl methylglycolate, butylphthalyl ethylglycolate, propylphthalyl butylglycolate, butylphthalyl propylglycolate, methylphthalyl octyiglycolate, ethylphthalyl octyiglycolate, octylphthalyl methylglycolate and octylphthalyl ethylglycolate.

A phthalic ester type plastisizer includes such as diethyl phthalate, dimethoxy ethylphthalate, dimethyl phthalate, dioctyl phthalate, dibutyl phthalate, di-2-ethyl hexylphthalate, dioctyl phthalate, dicyclohexyl phthalate and dicyclohexyl terephthalate.

A citric ester type plastisizer includes such as acetyltrimethyl citrate, acetyltrimethyl citrate and acetyltributyl citrate.

A fatty acid ester type plastisizer includes such as butyl oleate, methylacetyl ricinoleate and dibutyl cebacate.

A polyester type plastisizer is not specifically limited; however, a polyester plastisizer having an aromatic ring or a cycloalkyl ring in a molecule is preferably utilized. Preferable polyester type plastisizer is not specifically limited; however, an aromatic terminal ester type plastisizer represented by following general formula (2) is preferable.

B-(G-A)ₙ-G-B Formula (2)

(wherein, B is a benzene monocarboxylic acid residual group; G is an alkylene glycol residual group having a carbon number of 2-12, an aryl glycol residual group having a carbon number of 6-12 or an oxyalkylene glycol residual group having a carbon number of 4-12; A is an alkylene dicarboxylic acid residual group having a carbon number of 4-12 or an aryl dicarboxylic acid residual group having a carbon number of 6-12; and n is an integer of at least 1.)

General formula (2) is comprised of a benzene monocarboxylic acid residual group, which is represented by B; an alkylene glycol residual group, an oxyalkylene glycol residual group or an aryl glycol residual group, which is represented by G, and an alkylene dicarboxylic acid residual group or an aryl dicarboxylic acid residual group, which is represented by A; and can be prepared by a reaction similar to that of an ordinary polyester type plastisizer.

A benzene monocarboxylic acid component utilized in polyester type plastisizer of this invention includes such as benzoic acid, paratertiarybutylbenzoic acid, orthotoluic acid, methatoluic acid, paratoluic acid, dimethylbenzoic acid, ethylbenzoic acid, normal propylbenzoic acid, aminobenzoic acid and acetoxybenzoic acid, and these can be utilized alone or in combination of at least two types.

An alkylene glycol component of polyester type plastisizer having a carbon number of 2-12 includes such as ethylene glycol, 1,2-propylene glycol, 1,3-propylene glycol, 1,2-butandiol, 1,3-butandiol, 1,2-propanediol, 2-methyl-1,3-propanediol, 1,4-butanediol, 1,5-pentanediol, 2,2-dimthyl1,3-propanediol (neopentyl glycol), 2,2-diethyl-1,3-propanediol (3,3-dimethylolheptane), 2-n-butyl-2-ethyl1,3-propanediol, 1,6-hexanediol, 2,2,4-trimethyl-1,3-pentanediol, 2-ethyl-1,3-hexanediol, 2-metyl-1,8-octanediol, 1,9-nonanediol, 1,10-decanediol and 1,12-octadecanediol; and these glycol can be utilized alone or in combination of at least two types. Alkylene glycol having a carbon number of 2-12 is specifically preferable since the compatibility with cellulose ester is excellent.

Further, an oxyalkylene glycol component having a carbon number in aromatic terminal ester of 4-12 includes such as diethylene glycol, triethylene glycol, tetraethylene glycol, dipropylene glycol and tripropylene glycol; and these glycols can be utilized alone or in combination of at least two types.

An alkylene dicarboxylic acid component having a carbon number in aromatic terminal ester of 4-12 includes such as succinic acid, maleic acid, fumaric acid, gulutaric acid, adipic acid, azelaic acid, sebacic acid and dodecane dicarboxylic acid; and these can be utilized alone or in combination of at least two types. An arylene dicarboxylic acid component having a carbon number of 6-12 includes such as phthalic acid, terephthalic acid, isophthalic acid, 1,5-naphthalene dicarboxylic acid and 1,4-naphthalene dicarboxylic acid.

A polyester type plastisizer utilizable in this invention has a number average molecular weight of preferably 300-1,500 and more preferably 400-1,000. Further, the plastisizer is preferably provided with an acid value of not more than 0.5 mgKOH/g and a hydroxyl group value of not more than 25 mgKOH/g, and more preferably an acid value of not more than 0.3 mgKOH/g and a hydroxyl group value of not more than 15 mgKOH/g. In the following, a synthesis example of an aromatic ester type plastisizer will be shown.

### <Sample No. 1 (Aromatic Terminal Ester Sample)>

Phthalic acid of 410 parts, 610 parts of benzoic acid, 737 parts of dipropylene glycol and 0.40 parts of tetraisopropyl titanate as a catalyst were charged at one time in a reaction vessel, and were continuously heated at 130-250° C. until acid value reached not more than 2 while circulating excess monohydric alcohol employing a reflux condenser under nitrogen gas flow with stirring to remove generated water. Successively, distillate was removed under a reduced pressure of 100 Pa to finally of not more than 4×10² Pa at 200-230° C., followed by being filtered to prepare an aromatic terminal ester type plastisizer having the following properties.

Viscosity (25° C., mPa·s); 43,400

Acid value; 0.2

### <Sample No. 2 (Aromatic Terminal Ester Sample)>

An aromatic terminal ester type plastisizer having the following properties was prepared in a similar manner to sample No. 1 except that 410 parts of phthalic acid, 610 parts of benzoic acid, 341 parts of ethylene glycol and 0.35 parts of tetraisopropyl titanate as a catalyst were utilized.

Viscosity (25° C., mPa·s); 31,000

Acid value; 0.1

### <Sample No. 3 (Aromatic Terminal Ester Sample)>

An aromatic terminal ester type plastisizer having the following properties was prepared in a similar manner to sample No. 1 except that 410 parts of phthalic acid, 610 parts of benzoic acid, 418 parts of 1,2-propanediol and 0.35 parts of tetraisopropyl titanate as a catalyst were utilized.

Viscosity (25° C., mPa·s); 38,000

Acid value; 0.05

### <Sample No. 4 (Aromatic Terminal Ester Sample)>

An aromatic terminal ester type plastisizer having the following properties was prepared in a similar manner to sample No. 1 except that 410 parts of phthalic acid, 610 parts of benzoic acid, 418 parts of 1,3-propanediol and 0.35 parts of tetraisopropyl titanate as a catalyst were utilized.

Viscosity (25° C., mPa·s); 37,000

Acid value; 0.05

In the following, specific examples of an aromatic terminal ester type plastisizer will be shown; however, this invention is not limited thereto.

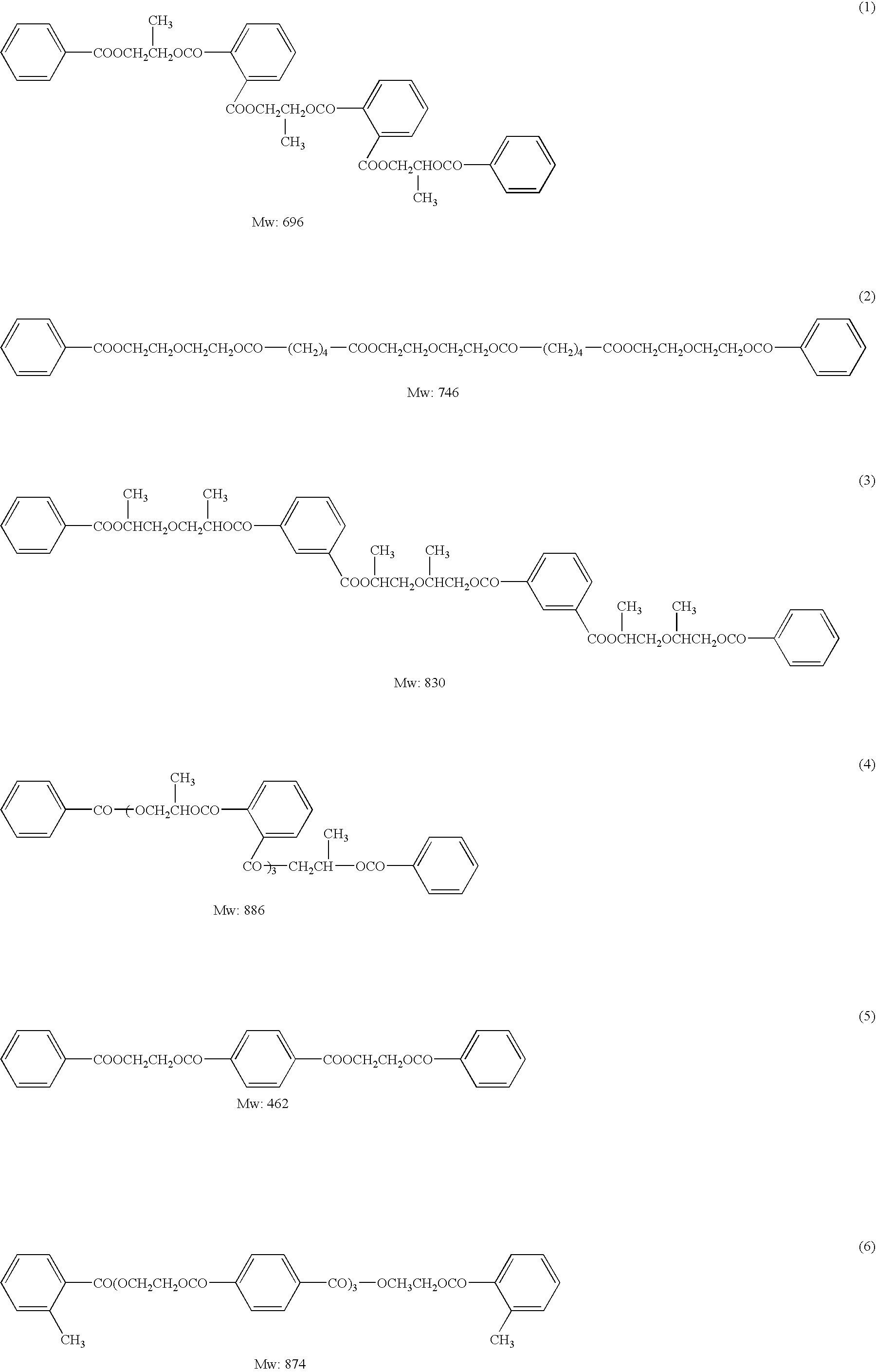

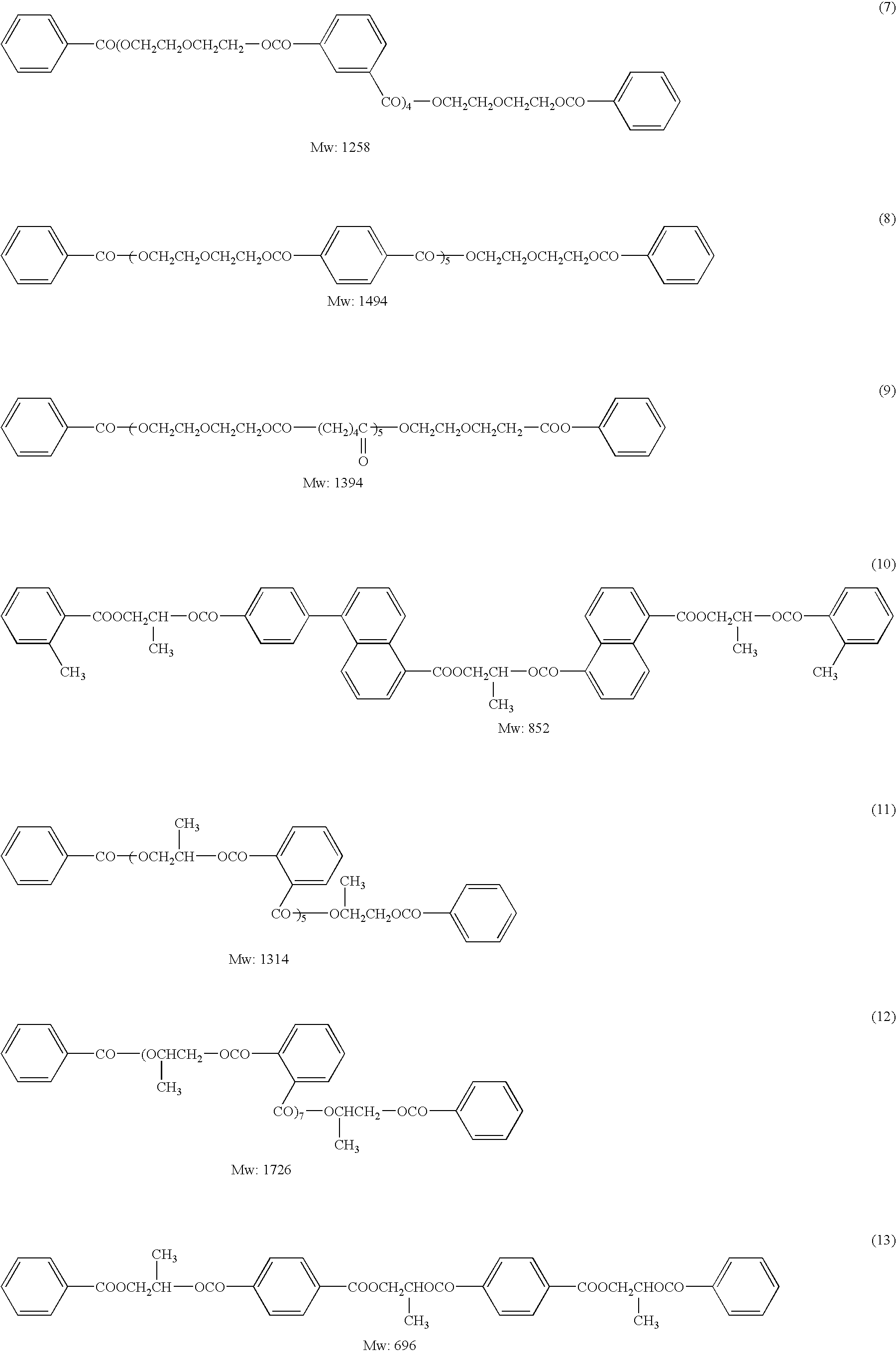

These plastisizers may be utilized alone or in combinations of at least two types. With respect to a using amount of a plastisizer, since an effect of decreasing moisture permeability is small when it is less than 1 weight %, while a plastisizer bleeds out from film to deteriorate physical properties of film when it is over 20 weight %, it is preferably 1-20 weight %. It is more preferably 6-16 weight % and specifically preferably 8-13 weight %.

An ultraviolet absorbent preferably utilized in this invention will be now explained.

In cellulose ester film, an ultraviolet absorbent described below is preferably incorporated with respect to prevention of deterioration when the film is placed outdoor as an image display.

As an ultraviolet absorbent, preferably utilized are those having an excellent absorbability of ultraviolet rays shorter than a wavelength of 370 nm and a small absorption of visible light longer than a wavelength of 400 nm. For example, listed are oxybenzophenone type compounds, benzotriazole type compounds, salicylic ester type compounds, benzophenone type compounds, diacrylate type compounds and nickel complex salt type compounds, however, this invention is not limited thereto.

Specific examples include, for example, the following compounds.

UV-1: 2-(2′-hydroxy-5′-methylphenyl)benzotriazole

UV-2: 2-(2′-hydroxy-3′,5′-di-tert-butylphenyl)benzotriazole

UV-3: 2-(2′-hydroxy-3′-tert-butyl-5′-methylphenyl)benzotriazole

UV-4: 2-(2′-hydroxy-3′,5′-di-tert-butylphenyl)-5-chlorobenzotriazole

UV-5: 2-(2′-hydroxy-3′-(3″,4″,5″,6″-tetrahydrophthalimidomethyl)-5′-methylphenyl)benzotriazole

UV-6: 2,2-methylenebis(4-(1,1,3,3-tetramethylbutyl)-6-(2H-benzotriazole-2-yl)phenol)

UV-7: 2-(2′-hydroxy-3′-tert-butyl-5′-methylphenyl)-5-chlorobenzotriazole

UV-8: 2,4-dihydroxybenzophenone

UV-9: 2,2′-dihydroxy-4-methoxybenzophenone

UV-10: 2-hydroxy-4-methoxy-5-sulfobenzophenone

UV-11: bis(2-methoxy-4-hydroxy-5-benzophenylmethane)

As an ultraviolet absorbent, preferably utilized are those having a superior absorption ability of ultraviolet rays of wavelength of not longer than 370 nm as well as having small absorption of visible light of wavelength of not shorter than 400 nm in view of an excellent liquid crystal displaying property. Ultraviolet absorption ability of optical film according to this invention is preferably a transmittance of not more than 10% against light of a wavelength of 380 nm, and more preferably a transmittance of less than 6% and specifically preferably a transmittance of less than 0-4%.

A content of ultraviolet absorbent utilized in optical film is determined to a suitable amount depending on required transmittance of light having a wavelength of 380 nm.

Further, compounds of a hindered phenol type are utilized as an antioxidant and include such as 2,6-di-t-butyl-p-crezole, pentaerythrityl-tetrakis[3-(3,5-di-t-butyl-4-hydroxyphenyl)propionate], triethylene glycol-bis[3-(3-t-butyl-5-methyl-4-hydroxyphenyl)propionate], 1,6-hexanediol-bis[3-(3,5-di-t-butyl-4-hydroxyphenyl)propionate], 2,4-bis-(n-octylthio)-6-(4-hydroxy-3,5-di-t-butylanilino)-1,3,5-triazine, 2,2-thio-diethylene bis[3-(3,5-di-t-butyl-4-hydroxyphenyl)propionate], octadecyl-3-(3,5-di-t-butyl-4-hydroxyphenyl)propionate, N,N′-hexamethylene bis(3,5-di-t-butyl-4-hydroxy-hydrocynamide), 1,3,5-trimethyl-2,4,6-tris(3,5-di-t-butyl-4-hydroxybenzyl)benzene and tris(3,5-di-t-butyl-4-hydroxybenzyl)-isocyanurate. Specifically preferable are 2,6-di-t-butyl-p-crezole, pentaerythrityl-tetrakis[3-(3,5-di-t-butyl-4-hydroxyphenyl)propionate] and triethylene glycol-bis[3-(3-t-butyl-5-methyl-4-hydroxyphenyl)propionate]. Further, a hydrazine type metal inactivator such as N,N′-bis[3-(3,5-di-t-butyl-4-hydroxyphenyl)propionyl]hydrazine; and a phosphor type stabilizer such as tris(2,4-di-t-butylphenyl)phosphate may be incorporated in combination. An addition amount of these compounds is preferably 1 ppm-1.0% a and more preferably 1-1,000 ppm based on a weight ratio against cellulose ester.

These antioxidants are referred to also as degradation restrainers. Cellulose ester may be deteriorated when such as a liquid crystal image display is placed under a state of high temperature and high humidity, and the antioxidants are preferably incorporated in cellulose ester film because of a role to retard or prevent decomposition of cellulose ester, for example, by halogen contained in a residual solvent or phosphoric acid from a phosphoric acid type plastisizer, in cellulose ester film.

Uniform optical film without unevenness of each layer can be prepared by a production method of this invention even when plural thin layers are accumulated.

In this manner, this invention can provide optical film comprised of thin layers having various functions.

In this invention, provided may be a layer, which is formed by coating metal oxide micro-particles or conductive resin micro-particles such as cationic polymer and has a layer thickness of 0.1-2 μm, as an antistatic layer or a conductive layer.

Optical film prepared by a processing method of optical film of this invention is specifically useful as polarizer protective film, and a polarizer can be prepared by employing the film according to a commonly known method. The optical films can be preferably utilized in various displays because of high uniformity of thin layers, whereby excellent display properties can be obtained.

A processing method of optical film of this invention is preferably employed when optical film is provided with a functional layer such as an antireflection layer, an anti-glare layer, a clear hard coat layer, an antistatic layer, an antistain layer, an optical diffusion layer, an optical isotropic layer, an orientation layer and a liquid crystal layer, and specifically employed at the time of coating process of polarizer protective film. Among them, it is specifically preferably employed at the time of production of an antireflection layer.

In a liquid crystal display, it is preferable that a substrate containing liquid crystal is generally arranged between two polarizers, however, since such as a hard coat layer, an antiglare layer and an antireflection layer are provided on a polarizer protective film at the outermost display side surface of a display, a polarizer is specifically preferably utilized at this portion.

### (Hard Coat Layer)

Long length roll-film, having been treated with a process according to this invention, is preferably provided with a hard coat layer.

Optical film of this invention is preferably provided with an antireflection layer on the hard coat layer to constitute antireflection film.

An actinic ray curable resin layer is preferably utilized as a hard coat layer.

An actinic ray curable resin layer refers to a layer comprising resin, which cures via such as a cross-linking reaction by actinic ray radiation of such as ultraviolet rays or electron rays, as a primary component. As actinic ray curable resin, a composition containing monomer having an unsaturated double bond is preferably utilized, which is cured by radiation of actinic rays such as ultraviolet rays and electron rays to form a hard coat layer. Actinic ray curable resin includes ultraviolet ray curable resin and electron ray curable resin as typical examples; however, resin curable with radiation of ultraviolet rays is preferable.

As ultraviolet ray curable resin, preferably utilized are such as ultraviolet ray curable urethane acrylate type resin, ultraviolet ray curable polyester type resin, ultraviolet ray curable epoxy acrylate type resin, ultraviolet ray curable polyol acrylate type resin or ultraviolet ray curable epoxy type resin.

Ultraviolet ray curable acryl urethane type resin can be easily prepared generally by reacting polyester polyol with isocyanate monomer or prepolymer and further reacting the resulting product with acrylate type monomer having a hydroxyl group such as 2-hydroxyethylacrylate, 2-hydroxyethylmethacrylate (hereinafter, only acrylate is described to include methacrylate) and 2-hydroxypropylacrylate. For example, those described in JP-A 59-151110 can be utilized.

For example, a mixture of 100 parts of Unidic 17-806 (produced by Dainippon Ink & Chemicals, Inc.) and 1 part of Coronate L (produced by Nippon Urethane Co., Ltd.) is preferably utilized.

Ultraviolet ray curable polyester acrylate type resin includes those easily prepared generally by reacting polyester polyol with monomer of a 2-hydroxyethylacrylate or 2-hydroxyaccrylate type, and those described in JP-A 59-151112 can be utilized.

Specific examples of ultraviolet ray curable epoxyacrylate type resin include the reaction product formed by adding a reactive diluting agent and a photoreaction initiator into epoxyacrylate as oligomer to be reacted, and those described in JP-A 1-105738 can be utilized.

Specific examples of ultraviolet ray curable polyol acrylate type resin include such as trimethylolpropane triacrylate, ditrimethylolpropane tetraacrylate, pentaerythritol triacrylate, pentaerythritol tetraacrylate, dipentaerythritol hexaacrylate and alkyl modified dipentaerythritol pentaacrylate.

A photoreaction initiator of the ultraviolet ray curable resin includes, specifically, benzoin and derivatives thereof; and acetophenone, benzophenone, hydroxybenzophenone, Michler's ketone, α-amyloxime ester, and thioxanthone and derivatives thereof. These may be utilized in combination with a photosensitizer. Photoinitiators described above can be also utilized as a photosensitizer. Further, a photosensitizer such as n-butylamine, triethylamine and tri-n-butylphosphine can be utilized at the time of employing a photoinitiator of an epoxyacrylate type. A photoinitiator or a photosensitizer utilized in an ultraviolet ray curable resin composition is incorporated at 0.1-15 weight parts and preferably 1-10 weight parts against 100 parts of the composition.

Resin monomer includes ordinary monomer such as methylacrylate, ethylacrylate, butylacrylate, benzylacrylate, cyclohexylacrylate, vinyl acetate and styrene, as monomer having one unsaturated double bond. Further, listed are such as ethyleneglycol diacrylate, propyleneglycol diacrylate, divinyl benzene, 1,4-cycloheane diacrylat, 1,4-cycloheane dimethylacrylate; and trimethylolpropane triacrylate and pentaerythritol tetraacrylate which are described above, as monomer having at least two unsaturated double bonds.

As a product available on the market of ultraviolet ray curable resin utilizable in this invention, employed by appropriate selection can be such as Adekaoptomer KR•BY series: KR-400, KR-410, KR-550, KR-566, KR-567 and BY-320B. (produced by Asahi Denka Co., Ltd.); Koeihard A-101-KK, A-101-WS, C-302, C401-N, C-501, M-101, M-102, T-102, D-102, NS-101, FT-102Q8, MAG-1-P20, AG-106 and M-101-C (produced by Koei Chemicals Co., Ltd.); Seikabeam PHC2210, PHC X-9 (K-3), PHC2213, DP-10, DP-20, DP30, P1999, P1100, P1200, P1300, P1400, P1500, P1600 and SCR900 (produced by Dainichi Seika Kogyo Co., Ltd.); KRM7033, KRM7039, KRM7130, KRM7131, UVECRYL29201 and UVECRYL29202 (produced by Daicel•U.C.B. Co., Ltd.); RC-5015, RC-5016, RC-5020, RC-5031, RC-5100, RC-5102, RC-5120, RC-5122, RC-5152, RC-5171, RC-5180 and RC-5181 (produced Dainippon Ink & Chemicals, Inc.); Olex No. 340 Clear (produced by Chugoku Marin Paints, Ltd.); Sunrad H-610, RC-750, RC-700, RC-700, RC-600 and RC-500 (produced by Sanyo Chemicals Co., Ltd.); SP-1509 and SP-1507 (produced by Syowa Polymer Co., Ltd.); RCC-15C (produced by Grace Japan Co., Ltd.); Aronix M-6100, M-8030 and M8060 (Toagosei Co., Ltd.)

Further, specific example compounds include such as trimethylolpropane triacrylate, dimethylolpropane tetraacdrylate, pentaerythritol triacrylate, pentaerythritol tetraacrylate, dipentaerythritol hexaacrylate and alkyl modified dipentaerythritol pentaacrylate.

These actinic ray curable resin layers can be coated by means of a commonly known method employing such as a gravure coater, a dip coater, a reverse coater, a wire bar coater, a die coater and an inkjet method.

As a light source to cure ultraviolet ray curable resin by a photo-curing reaction and to form a cured film layer, any light source provided generating ultraviolet rays can be utilized without limitation. For example, such as a low pressure mercury lamp, a medium pressure mercury lamp, a high pressure mercury lamp, an ultrahigh pressure mercury lamp, a carbon arc lamp, a metal halide lamp, a xenon lamp and a LED can be utilized. These light sources are preferably cooled with air or with water. The irradiation condition may differ depending on each lamp; however, irradiation quantity of actinic rays is preferably 5-500 mJ/cm² and specifically preferably 20-150 mJ/cm².

Further, nitrogen is preferably purged on the irradiated portion to reduce an oxygen concentration to 0.01-2%.

Further, at the time of irradiation of actinic rays, it is preferably performed while film is applied with tension in the conveying direction, and further preferably performed while film is applied with tension also in the width direction. The tension applied is preferably 30-300 N/m. A method to apply tension is not specifically limited and tension may be applied in the conveying direction on a back roller or may be applied in the width direction or biaxial direction with a tenter. Thereby, film having more excellent flatness can be prepared.

As an organic solvent of an ultraviolet ray curable resin coating solution, for example, utilized can be hydrocarbons (such as toluene and xylene), alcohols (such as methanol, ethanol, isopropanol, butanol and cyclohexanol), ketones (such as acetone, methyl ethyl ketone and methyl isobutyl ketone), esters (such as methyl acetate, ethyl acetate and methyl lactate), glycol ethers and other organic solvents, by suitable selection or mixing them. The above described organic solvent containing propyleneglycol monoalkylether (a carbon number of an alkyl group of 1-4) or propyleneglycol monoalkylether acetic acid ester (a carbon number of an alkyl group of 1-4) preferably at not less than 5 weight % and more preferably at 5-80 weight % is utilized.

Further, an ultraviolet ray curable resin composition coating solution is preferably added with a silicone compound. For example, such as polyether modified silicone oil is preferably added. A number average molecular weight of polyether silicone oil is 1,000-100,000 and preferably 2,000-500,000, and drying ability of a coated layer is significantly decreased when it is less than 1,000 while bleed out on the surface becomes significant when the number average molecular weight it is over 100,000.

Products of a silicone compound available on the market include DKQ8-779 (product name manufacture by Dow Corning Corp.), SF37771, SF8410, SF8411, SF8419, SF8421, SF8428, SH200, SH510, SH1107, SH3749, SH3771, BX16-034, SH3746, SH3749, SH3771, BX16-034, SH3746, SH3749, SH8400, SH3771M, SH3772M, SH3773M, SH3775M, BY-16-837, BY-16-839, BY-16-869, BY-16-870, BY-16-004, BY-16-891, BY-16-872, BY-16-874, BY22-008, BY22-012, FS-1265 (product name produced by Toray-Dow Corning Corp.), KF-101, KF-100T, KF351, KF352, KF353, KF354, KF355, KF615, KF618, KF945, KF6004, SiliconeX-22-945 and X22-160AS (product name produced by Shin-Etsu Chemical Industry Co., Ltd.), XF3940 and XF3949 (product names, produced by Toshiba Silicone Corp.), DisperoneLS-009 (produced by Kusumoto Chemicals Co., Ltd.), Grano1410 (Kyoei Fat & Oil Chemicals Industrial Co., Ltd.), TSF4440, TS4441, TS4445, TS4446, TS4452 and TS4460 (produced by Toshiba Silicone Corp.), BYK-306, BYK-330, BYK-307, BYK-341, BYK-344 and BYK-361 (Big Chemie Japan), L series by Nippon Unicar Co., Ltd. (such as L7001, L-7006, L7604 and L-9000), Y series, FZ series (such as FZ-2203, FZ-2206 and FZ-2207), which are preferably utilized.

These components enhance a coating ability on a substrate or an under-lying layer. When they are added in the outer-most layer of the accumulate, a water repelling property, an oil repelling property and an anti-stain property are enhanced as well as an effect to increase an abrasion resistance of the surface is exhibited. These components are preferably added in a range of 0.01-3 weight % against a solid component of a coating solution.

As a coating method of an ultraviolet ray curable resin composition coating solution, the aforesaid one can be utilized. A coating amount is suitably 0.1-30 μm and preferably 0.5-15 μm, based on a wet layer thickness. Further, a dry layer thickness is 0.1-20 μm and preferably 1-10 μm.

An ultraviolet ray curable resin composition is preferably irradiated with ultraviolet rays during or after drying, and time to obtain the aforesaid irradiation quantity of 5-150 mJ/cm² is preferably 0.1-5 minutes and more preferably 0.1-10 seconds with respect to curing efficiency of ultraviolet ray curable resin or operation efficiency.

An illuminance of these actinic ray irradiation portions is preferably 50-150 mW/cm².

Inorganic micro-particles or organic micro-particles may be incorporated in a curable resin layer thus obtained to prevent blocking, to enhance such as abrasion resistance, to provide an antiglare property or a light diffusing property, or to adjust a refractive index.

It is preferable to incorporate micro-particles in a hard coat layer utilized in this invention, and utilized micro-particles include such as silicon oxide, titanium oxide, aluminum oxide, zirconium oxide, magnesium oxide, calcium carbonate, talc, clay, burned kaolin, burned calcium silicate, hydrated calcium silicate, aluminum silicate, magnesium silicate and calcium phosphate. Specifically preferable are silicon oxide, titanium oxide, aluminum oxide, zirconium oxide and magnesium oxide.

Further, as organic micro-particles, incorporated can be polymethacrylic acid methylacrylate resin powder, polymethacrylic acid methyl acrylate resin powder, acryl styrene type resin powder, polymethyl methacrylate resin powder, silicone type resin powder, polystyrene type resin powder, polycarbonate resin powder, benzoganamine type resin powder, theramine type resin powder, polyolefin type resin powder, polyester type resin powder, polyamide type resin, polyimide type resin or polyfluoro ethylene type resin powder, into an ultraviolet ray curable composition. Specifically preferably listed are cross-linked polystyrene particles (such as SX-130H, SX-200H and SX-350H produced by Soken Chemicals Co., Ltd.) and polymethylmethacrylate type particles (such as MX150 and MX300 produced by Soken Chemicals Co., Ltd.).

A mean particle size of these micro-particles is preferably 0.005-5 μm and specifically preferably 0.01-1 μm. As for a ratio of micro-particles to an ultraviolet ray curable resin composition, micro-particles are preferably blended at 0.1-30 weight % against 100 parts of the resin composition.

An ultraviolet ray curable resin layer is preferably a clear hard coat layer having a center line mean roughness (Ra), which is defined by JIS B 0601, of 1-50 μm, or an antiglare layer having a Ra of 0.1-1 μm. A center line mean roughness (Ra) is preferably measured with a surface roughness meter of a light interference type, and, for example, can be measured by use of RST/PLUS produced by WYKO Co., Ltd.

Further, a hard coat layer utilized in this invention is preferably incorporated with an antistatic agent, and the antistatic agent is, for example, preferably a conductive material which contains at least one element selected from a group comprising Sn, Ti, In, Al, Zn, Si, Mg, Ba, Mo, W and V as a primary component and has a volume resistivity of not more than 107 Ω·cm.

The aforesaid antistatic agent includes metal oxides and a complex oxide compound.

Examples of metal oxide are preferably such as ZnO, TiO₂, SnO₂, Al₂O₃, In₂O₃, SiO₂, MgO, BaO, MoO₂ and V₂O₅ or complex oxide thereof, and specifically preferably ZnO, In₂O₃, TiO₂ and SnO₂. As an example containing a foreign atom, for example, addition of such as Al and In against ZnO, addition of such as Nb and Ta against TiO₂, or addition of such as Sb, Nb and halogen against SnO₂, is effective. An addition amount of these foreign atoms is preferably in a range of 0.01-25 mol % and specifically preferably in a range of 0.1-15 mol %. Further, a volume resistivity of these metal oxide powders is not more than 10⁷ Ω·cm and specifically not more than 10⁵ Ω·cm.

Further, it is also preferable to prepare an ultraviolet ray curable resin layer, which has roughness formed by an embossing method employing a roller (an embossing roller) the surface of which is provided with roughness, as an antiglare layer.

### (Antireflection Layer)

Optical film of this invention is preferably comprised of an antireflection layer as a functional layer provided further on the hard coat layer described above. Particularly, it is a low refractive index layer containing hollow micro-particles.

### (Low Refractive Index Layer)

A low refractive index layer utilized in this invention preferably contains hollow micro-particles, and more preferably contains such as silicon alkoxide, a silane coupling agent and a hardening agent in addition thereto.

### (Hollow Micro-Particles)

A low refractive index layer preferably contains the following hollow micro-particles.

Hollow micro-particles referred here are (1) complex particles comprising porous particles and a cover layer arranged on the surface of the porous particles, or (2) hollow particles having a hollow inside, which is filled with a solvent, a gas or a porous substance as the content. Herein, in a low refractive index layer coating solution, either (1) complex particles or (2) hollow particles may be contained, or the both may be contained.

Herein, a hollow particle is a particle having an inner hollow which is surrounded by a particle wall. The hollow is filled with a content which has been utilized at the time of preparation such as a solvent, a gas or a porous substance. A mean particle size of such inorganic micro-particles is preferably in a range of 5-300 nm and more preferably in a range of 10-200 nm. Utilized micro-particles are suitably selected corresponding to a thickness of a formed transparent layer, and preferably have a particle size in a range of ⅔- 1/10 of a layer thickness of a formed transparent layer such as a low refractive index layer. These inorganic micro-particles are preferably utilized by being dispersed in a suitable medium to prepare a low refractive index layer. As a dispersion medium, preferable are water, alcohol (such as methanol, ethanol and isopropyl alcohol) and ketone (such as methyl ethyl ketone and methyl isobutyl ketone) and ketone alcohol (such as diacetone alcohol).

Thickness of the cover layer of a complex particle or of the particle wall of a hollow particle is in a range of 1-20 nm and preferably in a range of 2-15 nm. In the case of a complex particle, the particle may not be completely covered resulting in an insufficient effect of a low refractive index when a thickness of the cover layer is less than 1 nm. While, porosity of a complex particle may be decreased resulting in an insufficient effect of a low refractive index when a thickness of the cover layer is over 20 nm. Further, in the case of a hollow particle, a particle shape may not be maintained when a thickness of the particle wall is less than 1 nm, while an effect of a low refractive index may not be sufficiently exhibited when the thickness is over 20 nm.

The aforesaid cover layer of a complex particle or the particle wall of a hollow particle is preferably comprised of silica as a primary component. A component other than silica may be contained in the cover layer of a complex particle or the particle wall of a hollow particle, and specifically includes such as Al₂O₃, B₂O₃, TiO₂, ZrO₂, SnO₂, CeO₂, P₂O₃, Sb₂O₃, MoO₃, ZnO₂ and WO₃. A porous particle constituting a complex particle includes one comprised of silica, one comprised of silica and an inorganic compound other than silica, and one comprised of such as CaF₂, NaF, NaAlF₆ and MgF. Among them a porous particle comprised of a complex oxide of silica and an inorganic compound other than silica is preferred. An inorganic compound other than silica includes one type or at least two types of such as Al₂O₃, B₂O₃, TiO₂, ZrO₂, SnO₂, CeO₂, P₂O₃, Sb₂O₃ MoO₃ ZnO₂ and WO₃. In such a porous particle, a mol ratio MOₓ/SiO₂, when silica is represented by SiO₂ and an inorganic compound other than silica is represented by oxide conversion (MOₓ), is preferably in a range of 0.0001-1.0 and preferably of 0.001-0.3. A porous particle having a mole ratio MOₓ/SiO₂ of less than 0.0001 is difficult to be prepared, and conductivity is not exhibited even when prepared. While, since a ratio of silica becomes small when a mol ratio MO_{X}/SiO₂ of a porous particle is over 1.0, a micro-pore volume becomes small and a particle having a low refractive index may not be prepared.

A micro-pore volume of such a porous particle is in a range of 0.1-1.5 ml/g and preferably of 0.2-1.5 ml/g. A particle having a sufficiently lowered refractive index can not be obtained when a micro-pore volume is less than 0.1 ml/g, while strength of a micro-particle may be decreased resulting in decreased strength of a prepared layer when the volume is over 15 ml/g.

Herein, a micro-pore volume of such porous particles can be determined by a mercury injection method. Further, a content of hollow particles includes a solvent, a gas or a porous substance utilized in particle preparation. In a solvent, such as a non-reacted substance of a particle precursor which is utilized in preparation of hollow particles, and a utilized catalyst may be contained. Further a porous particle substance includes those comprised of compounds exemplified in the aforesaid porous particles. These contents may be either comprised of a single component or a mixture of plural components.

As a production method of these inorganic micro-particles, preferably employed is, for example, a preparation method of complex oxide colloidal particles disclosed in paragraph Nos. [0010-[0033] of JP-A 7-133105. Specifically, in the case of complex particles comprised of silica and an inorganic compound other than silica, inorganic particles are produced by the following first-third processes.

The First Process: Preparation of Porous Particle Precursor

In the first process, alkaline aqueous solutions of a silica raw material and of an inorganic compound raw material are separately prepared, or a mixed aqueous solution of a silica raw material and an inorganic compound raw material is prepared, in advance, and these solutions are gradually added into an alkaline aqueous solution having a pH of not lower than 10 with stirring, depending on a complex ratio of an aimed complex oxide, whereby a porous particle precursor is prepared.

As a silica raw material, alkali metal, a silicate of ammonium or organic base is utilized. As a silicate of alkali metal, sodium silicate (water glass) and potassium silicate are utilized. Organic base includes a quaternary ammonium salt of such as tetraethylammonium salt, amines such as monoethanolamine, diethanolamine and triethanolamine. Herein, silicate of ammonium or silicate of organic base includes an alkaline solution in which such as ammonia, quaternary ammonium hydroxide, or amine compound is added into a silicic acid solution.

Further, as a raw material of an inorganic compound other than silica, the aforesaid conductive compound which is alkaline soluble is utilized.

A pH value of a mixed aqueous solution varies simultaneous with addition of these aqueous solutions; however, it is not specifically required to control the pH into a predetermined range. An aqueous solution finally reaches a pH determined by types and a mixing ratio of micro-particles. An addition speed of an aqueous solution is not specifically limited. Further, at the time of preparation of complex oxide particles, dispersion of seed particles may be also utilized as a starting material. The seed particles are not specifically limited, however, micro-particles of an inorganic compound such as SiO₂, AL₂O₃, TiO₂ and ZrO₂ or micro-particles of these complex oxides are utilized, and sol thereof can be generally utilize. Further, a porous particle precursor dispersion prepared by the above-described production method may be also utilized as seed particle dispersion. In the case of utilizing a seed particle dispersion, after pH of the seed particle dispersion has been adjusted to not less than 10, an aqueous solution of the aforesaid compound is added with stirring into the above-described alkaline aqueous solution. Also in this case, pH control of dispersion is not necessarily performed. In this manner, by employing seed particles, it is easy to control particle size of prepared porous particles resulting in preparation of particles having a uniform particle size.

A silica raw material and an inorganic raw material, described above, are provided with a high solubility at the alkaline side. However, when the both are mixed in a pH region of this high solubility, solubility of an oxoacid ion such as silicate ion and aluminate ion is decreased and these complex compounds may be precipitated to form micro-particles or may be precipitated on seed particles to cause particle growth. Therefore, pH control as in a conventional method is not necessarily performed at the time of precipitation and growth of micro-particles.

A complex ratio of silica to an inorganic compound other than silica in the first process is preferably in a range of 0.05-2.0 and more preferably in a range of 0.2-2.0 as a mole ratio of MO_{X}/SiO₂ when an inorganic compound against silica is converted into oxide (MOₓ). In this range, the smaller is a ratio of silica, the larger is a micro-pore volume of porous particles. However, when the mol ratio is less than 0.05, a micro-pore volume becomes small. In the case of preparing hollow particles, a mol ratio of MO_{X}/SiO₂ is preferably in a range of 0.25-2.0.

The Second Process: Elimination of Inorganic Compound other than Silica from Porous Particles

In the second process, at least a part of inorganic compounds other than silica (elements other than silicon and oxygen) is selectively eliminated from the porous particle precursor prepared in the first process. As a specific elimination method, inorganic compounds in a porous particle precursor are dissolution eliminated by utilizing such as mineral acid and organic acid, or ion exchange eliminated by being brought in contact with cation exchange resin.

Herein, a porous particle precursor prepared in the first process is comprised of micro-particles having a network structure which is formed by bonding of silica with a component element of an inorganic compound via oxygen. By eliminating inorganic compounds (elements other than silicon and oxygen) in this manner, porous particles having more porosity and a larger micro-pore volume can be prepared. Further by increasing the amount of inorganic compounds being eliminated from a porous particle precursor, it is possible to prepare hollow particles.

Further, it is preferable to form a silica protective layer prior to elimination of inorganic compounds other than silica from a porous particle precursor, by adding a silicate solution, which can be prepared by dealkalization of alkali metal salt of silica, or a hydrolyzing organic silicon compound, into porous particle precursor dispersion prepared in the first process. A thickness of a silica protective layer is suitably 0.5-15 nm. Herein, even when a silica protective layer is formed, it is possible to eliminate the aforesaid inorganic compounds other than silica from a porous particle precursor since a protective layer in this process is porous and thin in thickness.

By forming such a silica protective layer, it is possible to eliminate the aforesaid inorganic compounds other than silica from a porous particle precursor while keeping the particle shape. Further, at the time of forming a silica cover layer described later, a micro-pore of porous particles never clogged by the cover layer so that it is possible to form the silica cover layer described later without decreasing a micro-pore volume. Herein, since particles are never broken in the case of the amount of inorganic compounds being small, a protective layer is not necessarily formed.

Further, in the case of preparation of hollow particles, it is preferable to form this silica protective layer. In the case of preparation of hollow particles, a precursor of hollow particles, which is comprised of silica protective layer, a solvent and an un-dissolved porous solid in the silica protective layer, is obtained when inorganic compounds are eliminated, and then the cover layer described later is formed on the precursor of hollow particles, resulting in formation of hollow particles in which the formed cover layer becomes the particle wall.

The amount of a silica source to form the above described silica protective layer is preferably as small as possible within a range of maintaining the particle shape. When the amount of a silica source is excessively large, inorganic compounds other than silica may become difficult to be eliminated from a porous particle precursor due to an excessively thick protective layer. As a hydrolyzing organic silicon compound utilized to form a silica protective layer, preferably utilized is alkoxysilane represented by general formula RₙSi(OR′)₄₋ₙ [R, R′: a hydrocarbon group such as an alkyl group, an aryl group, a vinyl group and an acryl group, and n=0, 1, 2 or 3]. Specifically preferably utilized are tetraalkoxysilane such as tetramethoxysilane, tetraethoxysilane and tetraisopropoxysilane.

As an addition method, a solution, in which a small amount of alkali or acid as a catalyst is added into a mixed solution of these alkoxysilane, pure water and alcohol, is added into dispersion of the aforesaid porous particles, whereby silicate polymer formed by hydrolysis of alkoxysilane is precipitated on the surface of inorganic oxide particles. At this time, alkoxysilane, alcohol and a catalyst may be simultaneously added in the dispersion. Ammonia, hydroxide of alkali metal and amines can be utilized as an alkali catalyst. Further, various types of inorganic acid and organic acid can be utilized as an acid catalyst.

When a dispersion medium of a porous particle precursor is comprised of water alone or has a high ratio of water against an organic solvent, it is possible to form a silica protective layer by employing a silicate solution. In the case of employing a silicate solution, a predetermined amount of a silicate solution is added into dispersion and alkali is simultaneously added to precipitate a silicate solution on the porous particle surface. Herein, a silica protective layer may be prepared by employing a silicate solution and the above-described alkoxysilane in combination.

The Third Process: Formation of Silica Cover Layer

In the third process, such as a hydrolyzing organic silicon compound or a silicate solution is added into porous particle dispersion prepared in the second process, whereby the surface of the particles is covered with a polymer such as a hydrolyzing organic silicon compound or a silicate solution to form a silica cover layer.

As a hydrolyzing organic silicon compound utilized to form a silica cover layer, utilized can be alkoxysilane represented by general formula RₙSi(OR′)₄₋ₙ[R, R′: a hydrocarbon group such as an alkyl group, an aryl group, a vinyl group and an acryl group, and n=0, 1, 2 or 3], as described above. Specifically preferably utilized are tetraalkoxysilane such as tetramethoxysilane, tetraethoxysilane and tetraisopropoxysilane.

As an addition method, a solution, in which a small amount of alkali or acid as a catalyst is added into a mixed solution of these alkoxysilane, pure water and alcohol, is added into dispersion of the aforesaid porous particles (the hollow particle precursor in the case of hollow particles), whereby silicate polymer formed by hydrolysis of alkoxysilane is precipitated on the surface of porous particles (a hollow particle precursor in the case of hollow particles). At this time, alkoxysilane, alcohol and a catalyst may be simultaneously added in the dispersion. Ammonia, hydroxide of alkali metal and amines can be utilized as an alkali catalyst. Further, various types of inorganic acid and organic acid can be utilized as an acid catalyst.

When a dispersion medium of a porous particle precursor is comprised of water alone or has a high ratio of water against an organic solvent, it is possible to form a cover layer by employing a silicate solution. A silicate solution is an aqueous solution of low polymer of silicate which is prepared by subjecting an aqueous solution of alkali metal silicate such as water glass to an ion exchange treatment and dealkalization.

A silicate solution is added into dispersion of porous particles (a hollow particle precursor in the case of hollow particles), and alkali is simultaneously added to precipitate silicate low polymer on the surface of porous particles (a hollow particle precursor in the case of hollow particles). Herein, a silicate solution and the above-described alkoxysilane may be utilized in combination to form a cover layer. An amount of an organic silicon compound or a silicate solution is approximately an amount to sufficiently cover the surface of colloidal particles, and an organic silicon compound or a silicate solution is added in the dispersion at an amount to make a thickness of the finally obtained silica cover layer of 1-20 nm.

Next, dispersion of particles having been provided with a cover layer is subjected to a heat treatment. By a heat treatment, in the case of porous particles, a silica cover layer covering the porous particle surface becomes minute and dispersion of complex particles, in which porous particles are covered with a silica cover layer, is prepared. Further, in the case of a hollow particle precursor, formed cover layer becomes minute to make a particle wall, whereby dispersion of hollow particles provided with the hollow, which is filled with a solvent, a gas or a porous solid, is prepared.

The heating treatment temperature at this time is not specifically limited provided being capable to block the micro-pores of a silica cover layer, and is preferably in a range of 80-300° C. When the heating treatment temperature is lower than 80° C., a silica cover layer may not be blocked to become minute and treating time may be too long. While the heating treatment is performed for a long time at over 300° C., close particles may be formed not to achieve an effect of a low refractive index.

A refractive index of inorganic particles obtained in this manner is as low as less than 1.44. It is estimated that a refractive index decreases since such micro-particles maintain porosity of the porous particle interior or have a hollow inside.

A low refractive index layer utilized in this invention preferably contains a condensate, which is formed by hydrolysis and the following condensation reaction of an alkoxy silicon compound, in addition to hollow micro-particles. Particularly, preferably contained is SiO₂ sol comprising an alkoxy compound or a hydrolyzed product thereof represented by following general formula (3) or (4).

R¹—Si(OR²)₃ Formula (3)

Si(OR²)₄ Formula (4)

(wherein, R¹ is an organic group containing a methyl group, an ethyl group, a vinyl group, or an acryloyl group, a methacryloyl group, an amino group, or an epoxy group; R² is a methyl group or an ethyl group.)

Hydrolysis of silicon alkoxide or a silane coupling agent is preformed by dissolving silicon alkoxide or a silane coupling agent in a suitable solvent. A solvent utilized includes ketones such as methyl ethyl ketone, alcohols such as methanol, ethanol, isopropyl alcohol and butanol, esters such as ethyl acetate, or mixtures thereof.

In to a solution, in which the above-described silicon alkoxide or a silane coupling agent is dissolved, added is a slightly larger amount of water than required for hydrolysis and stirred at 15-35° C. and preferably at 20-30° C., for 1-48 hours and preferably for 3-36 hours.

A catalyst is preferably utilized in the above hydrolysis, and as such a catalyst utilized is acid such as hydrochloric acid, nitric acid and sulfuric acid. These acid are utilized as an aqueous solution having a concentration of approximately 0.001-20.0 N and preferably of approximately 0.005-5.0 N.

An alkoxy silane compound is subjected to a hydrolysis reaction for a predetermined period, the prepared alkoxy silane hydrolyzed solution being diluted with a solvent, such as necessary other additives being added, and a low referactive index layer coating solution is prepared, which is coated on a substrate such as film and dried, whereby a low refractive index layer can be formed on a substrate.

### (Alkoxy Silane Compound)

In this invention, alkoxy silane compounds (hereinafter, also referred to as alkoxy silane) utilized for preparation of a low refractive index layer are preferably those represented by following general formula (5).

R₄-nSi(OR′)ₙ Formula (5)

wherein, R′ is an alkyl group, R is a hydrogen atom or a mono-valent substituent, and n is 3 or 4.

An alkyl group represented by R′ includes a group such as a methyl group, an ethyl group, a propyl group and a butyl group, which may be provided with a substituent. The substituent is not specifically limited provided exhibiting properties of alkoxy silane, and may be a halogen atom such as fluorine or an alkoxy group, however, an unsubstituted alkyl group is more preferable and a methyl group or an ethyl group is specifically preferable.

A mono-valent substituent represented by R is not specifically limited, however, includes such as an alkyl group, a cycloalkyl group, an alkenyl group, an aryl group, an aromatic heterocyclic group and a silyl group. Among them preferable are an alkyl group, a cycloalkyl group and an alkenyl group. These may be further substituted. A substituent of R includes a halogen atom such as a fluorine atom and a chlorine atom, an amino group, an epoxy group, a mercapto group, a hydroxyl group and an acetoxy group.

Preferable examples of an alkoxysilane represented by aforesaid Formula (5) specifically includes tetramethoxysilane, tetraethoxysilane (TEOS), tetra-n-propoxysilane, tetra-n-butoxysilane, tetra-t-butoxysilane, tetrakis(methoxyethoxy)silane and tetrakis(methoxypropoxy)silane; or methyltrimethoxysilane, methyltriethoxysilane, ethyltrimethoxysilane, ethyltriethoxysilane, n-propyltrimethoxysilane, n-propyltriethoxysilane, n-butyltrimethoxysilane, i-butyltrimethoxysilane, n-hexyltrimethoxysilane, 3-glicidoxypropyltrimethoxysilane, 3-aminopropyltriethoxysilane, 2-(3,4-epoxycyclohexyl)ethyltrimethoxysilane, 3-chloropropyltrimethoxysilne, 3-mercaptopropyltrimethoxysilane, acetoxytriethoxysilane, (heptadecafluoro-1,1,2,2-tetrahydrodecyl)trimethoxysilane, (3,3,3-trifluoropropyl)trimethoxysilane, (3,3,3-trifluoropropyl)triethoxysilane and pentafluorophenylpropyltrimethoxysilane; and further, vinyltrimethoxysilane, vinyltriethoxysilne and phenyltrimethoxysilane.

Further, a silicon compound of oligomer such as Silicate 40, Silicate 45, Silicate 48 and M Silicate 51, produced by Tama Chemicals Co., Ltd., in which the above described compounds are partly condensed can be also utilized.

Since the aforesaid alkoxysilane is provided with a silicon alkoxide group which is capable of hydrolysis polycondensation, a network of a polymer compound structure is formed by cross-linking due to hydrolysis and condensation of these alkoxysilane, and utilizing the resulting product as a low refractive index layer coating solution to be coated on a substrate and dried, whereby a uniform layer containing silicon oxide is formed on a substrate.

The hydrolysis reaction can be carried out by a commonly known method, and alkoxysilane is hydrolyzed and condensed by addition of a hydrolysis catalyst after having been dissolved and mixed in the presence of a predetermined amount of water and a hydrophilic organic solvent such as methanol, ethanol and acetonitrile so as to make hydrophobic alkoxysilane and water easily miscible. Generally, by a hydrolysis and condensation reaction at 10-100° C., liquid silicate oligomer having at least two hydroxyl groups is produced to form a hydrolyzed solution. The degree of hydrolysis can be adjusted by an amount of utilized water.

In this invention, methanol and ethanol are preferred as a solvent added together with water since the cost is low and an obtained cover layer exhibits excellent characteristics and superior hardness. Such as isopropanol, n-butanol, isobutanol and octanol can be also utilized; however, there is a tendency of decreasing of hardness of an obtained cover layer. The amount of a solvent is 50-400 weight parts and preferably 100-250 weight parts against 100 parts of tetraalkoxysilane before hydrolysis.

A hydrolyzing solution prepared in this manner, which is diluted by a solvent and appropriately added with an additive, is mixed with necessary components to form a low refractive index layer coating solution, whereby a low refractive index layer coating solution is prepared.

### (Hydrolysis Catalyst)

A hydrolysis catalyst includes such as acid, alkali, organic metal and metal alkoxide, however, in this invention, inorganic acid such as sulfuric acid, hydrochloric acid, nitric acid, hydrochlorous acid and boric acid, or organic acid is preferable; more preferable are nitric acid, carboxylic acid such as acetic acid, polyacrylic acid, benzene sulfonic acid, paratoluene sulfonic acid and methylsulfonic acid; and among them, specifically preferably utilized are nitric acid, acetic acid, citric acid and tartaric acid. In addition to citric acid and tartaric acid, also preferably utilized are such as levulinic acid, formic acid, propionic acid, malic acid, succinic acid, methylsuccinic acid, fumaric acid, oxaloacetic acid, pyruvic acid, 2-oxoglutaric acid, glycolic acid, D-glyceric acid, D-gluconic acid, malonic acid, maleic acid, oxalic acid, isocitric acid and lactic acid.

Among them, those in which acid evaporates during drying and does not remain in the film are preferable, that is, those having a low boiling point are preferred. Therefore, acetic acid and nitric acid are specifically preferable.

The addition amount is 0.001-10 weight parts and preferably 0.005-5 weight parts against 100 weight parts of a utilized alkoxysilane compound (such as tetraalkoxysilane). Further, the addition amount of water is not less than an amount which enables theoretical 100% hydrolysis of a partially hydrolyzed compound, and is 100-300% equivalent amount and preferably 100-200% equivalent amount.

At the time of hydrolysis of the above-described alkoxysilane, inorganic micro-particles described below are preferably blended.

The hydrolyzing solution is left for a predetermined time after hydrolysis starts and is utilized after the progress of hydrolysis reaches a predetermined level. Leaving time is a time as long as cross-linking by the above-described hydrolysis and condensation to sufficiently proceed to obtain desired film characteristics. Specifically, although it depends on an employed catalyst, it is not less than 15 hours at room temperature in the case of acetic acid, and is preferably not less than 2 hours in the case of nitric acid. Ripening temperature influences ripening time, and ripening generally proceeds fast at high temperature, however, heating and keeping warm at 20-60° C. is suitable since gelation may be caused when the temperature is not lower than 100° C.

Hollow micro-particles and an additive described above are added into a silicate oligomer solution, which has been formed by hydrolysis and condensation in this manner, and are subjected to necessary dilution to prepare a low refractive index layer coating solution, which is coated on the aforesaid film and dried, whereby a layer containing a silicon oxide film excellent as a low refractive index layer can be prepared.

Further, in this invention, in addition to alkoxysilane described above, modified compounds modified by such as a silane compound (monomer, oligomer or polymer) having a functional group such as an epoxy group, an amino group, an isocyanate group and carboxyl group may be also utilized alone or in combination.

### (Fluorine Compound)

A low refractive index layer utilized in this invention may be comprised of a fluorine compound as a primary component, and also preferably contains hollow micro-particles and a fluorine compound. The layer preferably contains fluorine-containing resin (hereinafter, also referred to as pre-cross-linked fluorine-containing resin), which is cross-linked by heat or ionizing radiation, as a binder matrix. It is possible to provide an excellent antistaining antireflection film by incorporating the fluorine resin.

Pre-cross-linked fluorine-containing resin preferably includes fluorine-containing copolymer formed from fluorine-containing vinyl monomer and monomer to provide a cross-linking group. Specific examples of the fluorine-containing vinyl monomer described above include fluoroolefins (such as fluoroethylene, vinylidenefluoride, tetrafluoroethylene, hexafluoroethylene, hexafluoropropylene and perfluoro-2,2-dimethyl-1,3-dioxole), partially or completely fluorinated alkyl ester derivatives of methacrylic acid) (such as biscoat (Biscoat 6FM (produced by Osaka Organic Chemicals co., Ltd.)), M-2020 (produced by Daikin co. Ltd.) and completely or partially fluorinated vinyl ethers. Monomer to, provide a cross-linking group includes vinyl monomer having a cross-linking functional group in a molecule in advance such as glycidylmethacrylate, vinylmethoxysilane, γ-methacryloyloxypropyl trimethoxysilane and vinylglycidyl ether, in addition to vinyl monomer having a carboxyl group, a hydroxyl group, an amino group and a sulfonate group (such as ((meth)acrylic acid, methylol (meth)acrylate, hydroxyalkyl (meth)acrylate, arylacrylate, hydroxyalkyl vinylether and hydroxyalkyl arylether). The latter can be introduced with a cross-linking group by addition of a compound, which is provided with a group to react with a functional group in polymer and at least one reactive group, after copolymerization; this is described in JP-A Nos. 10-25388 and 10-147739. Examples of a cross-linking group include groups of such as acryloyl, methacryloyl, isocyanate, epoxy, adiridine, aldehyde, carbonyl, hydrazine, carboxyl, methylol and active methylene. The resin is a thermal curing type in the case of comprising a cross-linking group reactive with heat, a combination of an ethylenic unsaturated group and a thermo-radical generator, or an epoxy group and a thermo-acid generator, and fluorine containing copolymer being cross-linked by heating; while the resin is a ionizing radiation curing type in the case of comprising a combination of an ethylenic unsaturated group and a photo-radical generator, or an epoxy group and a photo-acid generator, and fluorine containing copolymer being cross-linked by irradiation of light (preferably such as ultraviolet rays and electron rays).

Further, in addition to the above described monomer, fluorine-containing copolymer, which has been formed utilizing fluorine-containing vinyl monomer, and monomer other than monomer to provide a cross-linking group in combination may be utilized as pre-cross-linked fluorine-containing resin. Utilizable monomer is not specifically limited and can include olefins (such as ethylene, propylene, isoprene, vinyl chloride and vinilidene chloride), acrylic esters (such as methylacrylate, ethyl acrylate 2-ethylhexyl acrylate), methacrylic esters (methyl methacrylate, ethyl methacrylate, butyl methacrylate and ethyleneglycol dimethacrylate), styrene derivatives (such as styrene, divinylbenzene, vinyltoluene and α-methylstyrene), vinyl ethers (such as methylvinyl ether), vinyl esters (such as vinyl acetate, vinyl propionate and vinyl cinnamate), acrylic amides (such as N-tert-butylacrylamide and N-cyclohexyl acrylamide), methacrylic amides and acrylonitrile derivatives. Further, in fluorine-containing copolymer, such as a polyorganosiloxane skeleton or a perfluoropolyether skeleton is preferably introduced to provide a sliding property and an antistain property. This can be prepared by such as polymerization of polyorganosiloxane or perfluoropolyether having such as an acryl group, a methacryl group, a vinylether group and a styryl group at the terminal and the above-described monomer, polymerization of polyorganosiloxane or perfluoropolyether having a radical generating group at the terminal and the above-described monmer, and polymerization of polyorganosiloxane or perfluoropolyether having a functional group and fluorine-containing copolymer.

The ratio of each monomer described above which is utilized to form pre-cross-linked copolymer is preferably 20-70 mol % and more preferably 40-70 mol % of fluorine-containing vinyl monomer, 1-20 mol % and more preferably 5-20 mol % of monomer to provide a cross-linking group, and 10-70 mol % and more preferably 10-50 mol % of other monomer utilized in combination.

Fluorine-containing copolymer can be prepared by polymerization of these monomers in the presence of a radical polymerization initiator by means of such as solution polymerization, emulsion polymerization and suspension polymerization.

Pre-cross-linked fluorine-containing resin is available on the market, which can be utilized. Examples of pre-cross-linked fluorine-containing resin available on the market include Cytop (produced by Asahi Glass Co., Ltd.), Teflon (registered mark), AF (produced by Dupont), polyfluorovinylidene, Lumiflon (produced by Asahi Glass Co., Ltd.) and Opstar (produced by JSR).

A low refractive index layer comprising cross-linked fluorine-containing resin as a constituent component has a dynamic friction coefficient of a range of 0.03-0.15, a contact angle against water of a range of 90-120 degrees.

### <Additives>

In a low refractive index layer coating solution, an additive such as a silane coupling agent and a hardener may be incorporated. A silane coupling agent is specifically includes such as vinyl triethopxysilane, γ-methacryloxypropyl trimethoxysilane, γ-glycidoxypropyl trimethoxysilane and 3-(2-aminoethylaminopropyl) trimethoxysilane.

A hardener includes metal salt of organic acid such as sodium acetate and lithium acetate, and specifically preferably sodium acetate. The addition amount against an alkoxysilane hydrolyzing solution is preferably in a range of approximately 0.1-1 weight part against 100 parts of the solid content in the hydrolyzing solution.

Further, various types of low surface tension substances such as a leveling agent, a surfactant and silicone oil are preferably added into a low refractive index layer coating solution of this invention.

As silicone oil, specific products include L-45, L-9300, FZ-3704, FZ-3703, FZ-3720, FZ-3786, FZ-3501, FZ-3504, FZ-3508, FZ-3705, FZ-3707, FZ-3710, FZ-3750, FZ-3760, FZ-3785 and Y-7499, produced by Nippon Unicar Co., Ltd.; and KF96L, KF96, KF96H, KF99, KF54, KF965, KF968, KF995, KF351, KF352, KF353, KF354, KF355, KF615, KF618, KF945, KF6004 and FL100, produced by Shin-Etsu Chemical Co., Ltd.

These components enhance coating behavior on a substrate or an under-lying layer. When being added in the outermost layer of an accumulate, they will not only enhance water repelling, oil repelling and anti-staining properties, but also exhibit an effect to improve abrasion resistance of the surface. These components are preferably added in a range of 0.01-3 weight % against the solid component in a coating solution because the excess addition may cause repellency spots at the time of coating.

### <Solvent>

A solvent utilized at the time of coating a low refractive index layer includes alcohols such as methanol, ethanol, 1-propanol, 2-propanol and butanol; ketones such as acetone, methyl ethyl ketone and cyclohexanone; aromatic hydrocarbons such as benzene, toluene and xylene; glycols such as ethylene glycol, propylene glycol and hexylene glycol; glycol ethers such as ethylcellosolve, butylcellosolve, ethycarbitol, butylcarbitol, diethylcellosolve, diethylcarbitol and propylene glycol monomethylether; N-methylpyrrolidone, dimethylformamide, methyl lactate, methyl acetate, ethyl acetate and water, which can be utilized alone or in combination of at least two types.

### <Coating Method>

As a coating method of a low refractive index layer, a coating method well known in the art such as dipping, spin coat, knife coat, bar coat, air doctor coat, blade coat, squeeze coat, reverse roller coat, gravure coat, curtain coat, spray coat and die coat or a commonly known inkjet method can be employed, and a coating method enabling continuous coating or thin layer coating is preferably employed. A coating amount is suitably 0.1-30 μm and preferably 0.5-15 μm, based on a wet layer thickness. A coating speed is preferably 10-100 m/min.

At the time of coating a composition of this invention on a substrate, it is possible to control such as layer thickness and coating uniformity by adjusting a solid content in a coating solution and a coating amount.

In this invention, further the following medium refractive index layer and high refractive index layer are preferably provided to form an antireflection layer comprising plural layers.

Constitutional examples of an antireflection layer utilizable in this invention are shown below; however, this invention is not limited thereto.

Long length roll-film/hard coat layer/low refractive index layer

Long length roll-film/hard coat layer/medium refractive index layer/low refractive index layer

Long length roll-film/hard coat layer/high refractive index layer/low refractive index layer

Long length roll-film/hard coat layer/medium refractive index layer/high refractive index layer/low refractive index layer

Long length roll-film/antistatic layer/hard coat layer/medium refractive index layer/high refractive index layer/low refractive index layer

Long length roll-film/hard coat layer/antistatic layer/medium refractive index layer/high refractive index layer/low refractive index layer

Antistatic layer/long length roll-film/hard coat layer/medium refractive index layer/high refractive index layer/low refractive index layer

Long length roll-film/hard coat layer/high refractive index layer/low refractive index layer/high refractive index layer/low refractive index layer

### (Medium Refractive Index Layer, High Refractive Index Layer)

A constitutional component of a medium refractive index layer and a high refractive index layer are not specifically limited provided obtaining a predetermined refractive indexes, however, are preferably comprised of such as the following metal oxide micro-particles having a high refractive index and a binder. Other additives may be incorporated. A refractive index of a medium refractive index layer is preferably 1.55-1.75 and a refractive index of a high refractive index layer is preferably 1.75-2.20. A thickness of a high refractive index layer and a medium refractive index layer is preferably 5 nm-1 μm, more preferably 10 nm-0.2 μm and most preferably 30 nm-0.1 μm. Coating can be performed in a similar manner to a coating method of the aforesaid low refractive index layer.

### <Metal Oxide Micro-Particles>

Metal oxide micro-particles are not specifically limited, and for example, titanium dioxide, aluminum oxide (alumina), zirconium oxide (zirconia), zinc oxide, antimony doped tin oxide (ATO), anthimony pentaoxide and iron oxide can be utilized as a primary component. Further, a mixture thereof is also utilized. When titanium oxide is utilized, preferred are metal oxide particles having a core/shell structure comprising titanium dioxide as a core, which is covered with such as alumina, silica zirconia, ATO, ITO and antimony pentaoxide, with respect to restraining photo-catalytic activity.

A refractive index of metal oxide micro-particles is preferably 1.80-2.60 and more preferably 1.90-2.50. A mean primary particle size of metal oxide micro-particles is preferably 5-200 nm and more preferably 10-150 nm. When the particle size is too small, metal oxide micro-particles are liable to aggregate to deteriorate dispersibility. When the particle size is too large, haze may be increased, which is not preferable. A shape of inorganic micro-particles is preferably a rice grain form, a needle form, a spherical form, a cubic form, a corn form or an irregular form.

Metal oxide micro-particles may be surface treated with an organic compound. Examples of an organic compound utilized for the surface treatment include polyol, alkanol amine, stearic acid, a silane coupling agent and a titanate coupling agent. Among them most preferable is a silane coupling agent described later. Surface treatments of at least two types may be utilized in combination.

A high refractive index layer and a medium refractive index layer having desired refractive indexes can be prepared by suitably selecting the type and addition ratio of metal oxide.

### <Binder>

A binder is incorporated to improve a film forming property or physical properties of a coated layer. As a binder, for example, the aforesaid ionizing radiation curable resin, acrylamide derivatives, polyfunctional acrylate, acrylic resin and methacrylic resin can be utilized.

### <Metal Compound, Silane Coupling Agent>

A metal compound and a silane coupling agent may be incorporated as other additives. A metal compound and a silane coupling agent can be utilized also as a binder.

As a metal compound, a compound represented by following Formula (6) or a chelating compound thereof can be utilized.

AₙMBₓ₋ₙ Formula (6)

In above Formula (6), M is a metal atom, A is a functional group capable of being hydrolyzed, or a hydrocarbon group having a functional group capable of being hydrolyzed, B is an atomic group covalently bonded or ionicaly bonded to metal atom M. “x” is an atomic valence of metal atom M, and “n” is an integer of not less than 2 and not more than “x”.

Functional group A capable of being hydrolyzed includes such as an alkoxy group, halogen such as a chlorine atom, an ester group and an amide group. Metal compounds belonging to above-described Formula (6) include alkoxide having at least two alkoxy groups which directly bond to a metal atom, and chelating compounds thereof. Preferable metal compounds include titanium alkoxide, zirconium alkoxide, silicon alkoxide and chelating compounds thereof, with respect to a reinforcement effect of refractive index and coated layer strength, handling easiness and material cost. Titanium alkoxide exhibits a rapid reaction rate and a high refractive index as well as easy handling; however, light fastness may be deteriorated when being added at a large amount. Zirconium alkoxide shows a high refractive index, however, such as control of a dew point should be taken care at the time of coating because of easy milky whitening. Silicon alkoxide exhibits a slow reaction rate and a low refractive index, but easy handling and excellent light fastness. A silane coupling agent can react with both of inorganic micro-particles and organic polymer, resulting in formation of a strong coated layer. Further, since titanium alkoxide has an effect to accelerate the reaction of ultraviolet ray curable resin and metal alkoxide, it can improve physical properties of a coated layer even with a small amount addition.

Titanium alkoxide includes such as tetramethoxytitane tetraethoxytitane, tetra-iso-propoxytitane, tetra-n-propoxytitane, tetra-n-butoxytitane, tetra-sec-butoxytitane and tetra-tert-butoxytitane.

Zirconium alkoxide includes such as tetramethoxyzirconium, tetraethoxyzirconium, tetra-iso-propoxyzirconium, tetra-n-propoxyzirconium, tetra-n-butoxyzirconium, tetra-sec-butoxyzirconium and tetra-tert-butoxyzirconium.

Silicon alkoxide and a silane coupling agent are compounds represented by following general formula (7).

RₘSi(OR′)ₙ Formula (7)

In above Formula (6), R is a reactive group such as an alkyl group (preferably an alkyl group having a carbon number of 1-10), or a vinyl group, a (meth)acryloyl group, an epoxy group, an amide group, a sulfonyl group, a hydroxyl group, a carboxyl group and an alkoxyl group, R' is an alkyl group (preferably an alkyl group having a carbon number of 1-10), and “m+n” is 4.

Specifically listed are tetramethoxysilane, tetraethoxysilane, tetra-iso-propoxysilane, tetra-n-propoxysilnae, tetra-n-butoxysilane, tetra-sec-butoxysilane, tetra-tert-butoxysilane, tetrapentaethoxysilane, methyltrimethoxysilane, methyltriethoxysilane, methyltripropoxysilane, methyltributoxysilane, dimethyldimethoxysilane, dimethyldiethoxysilane, hexyltrimethoxysilane, vinyl triethoxysilne, γ-methacryloxypropyl trimethoxysilane, γ-glycidoxypropyl trimethoxysilane and 3-(2-aminoethylaminopropyl)trimethoxysilane.

A chelating agent, which is preferable to coordinate to a free metal compound to form a chelate compound, includes alkanol amines such as diethanol amine and triethanol amine, glycols such as ethylene glycol, diethylene glycol and propylene glycol, acetyl acetone and ethyl acetoacetate, which has a molecular weight of not more than 10,000. By employing these chelating agents, a chelate compound, which is stable against mixing of water and excellent in reinforcement effect of a coated layer, can be prepared.

An addition amount of a metal compound is preferably less than 5 weight % in a medium refractive index layer composition, and is preferably less than 20 weight % in a high refractive index layer composition, as a converted metal oxide.

In a treatment of long length roll-film by a processing method of this invention, film substrate, after having been subjected to a process, is preferably coated with each layer of the aforesaid actinic ray curable resin layer or antireflection layer; or it is also preferable to perform this treatment after an actinic ray curable resin layer is provided but before an antireflection layer is coated; or plural times of treatments can be performed in each of these processes.

### (Polarizer)

Optical film of this invention is useful as polarizer protective film, and the polarizer can be prepared by a general method. Optical film of this invention, the rear surface of which is subjected to an alkali saponification treatment, is preferably pasted up on at least one surface of polarizing film, which has been prepared by immersing and stretching in an iodine solution, by use of a completely saponificated polyvinyl alcohol solution. On the other surface, either optical film of this invention or other polarizer protective film may be utilized. Cellulose ester film available on the market (for example, Konica Minolta TAC KC8UX, KC4UX, KC5UX, KC8UCR3, KC8UCR4, KC8UY, KC4UY, KC12UR, KC8UCR-3, KCUCR-4 and KC8UCR-5, produced by Konica Minolta Opto, Inc.) can be also preferably utilized. Polarizer protective film utilized on the other surface is preferably provided with an inner-plane retardation Ro of 30-300 nm and a phase difference Rt of 70-400 nm at a measurement wavelength of 590 nm. These can be prepared by a method described in JP-A 2000-71957 and Japanese Patent Application No. 2002-155395. Further, it is preferable to utilize polarizer protective film, which is provided with an optical isotropic layer formed by orientating a liquid crystal compound such as discotic liquid crystal and functions as optical compensation film at the same time. For example, an optical isotropic layer can be formed by a method described in JP-A 2003-98348. By utilizing the layer in combination with optical film of this invention, a polarizer having an excellent flatness and a stable view angle enlargement effect can be obtained.

Polarizing film as a primary constituent element of a polarizer is an element, which passes only light having a polarized wave plane of a certain direction, and typical polarizing film known at present is polyvinyl alcohol type film, which includes polyvinyl alcohol type film dyed with iodine and one dyed with dichroic dye. As polarizing film, polyvinyl alcohol aqueous solution is cast, and the cast film being dyed after uniaxial stretching, or one having been uniaxially stretched after dying, preferably followed by being subjected to a durability treatment by a boron compound, is utilized. A layer thickness of polarizing film is preferably 5-30 μm and specifically preferably 10-20 μm.

Further, ethylenic modified polyvinyl alcohol, which is described in JP-A Nos. 2003-248123 and 2003-342322, and having a content of an ethylene unit of 1-4%, a polymerization degree of 2,000-4,000 and a saponification degree of 99.0-99.99, is also preferably utilized. Among them, ethylenic modified polyvinyl alcohol film having a hydrothermal cut temperature of 66-73° C. is preferably utilized. A polarizing film employing this ethylenic modified polyvinyl alcohol film is specifically preferably utilized for a large liquid crystal display because of an excellent polarizing ability and durability in addition to minimum colored speckles.

Polarizing film prepared in the above manner is generally utilized as a polarizer by being pasted up with polarizer protective film on the both surfaces or one surface. An adhesive utilized at the time of pasting up includes such as a PVA type adhesive and a urethane type adhesive, however, among them preferably utilized is a PVA type adhesive.

### (Display)

Various types of displays having excellent visual recognition ability can be prepared by incorporating a polarizer, in which optical film of this invention is utilized, into a display. Optical film of this invention is preferably utilized in a reflection type, a transparent type and a translucent type LCD's or LCD's having various driving methods such as a TN type, a ST type, an OCB type, a HAN type, a VA type (a PVA type and a MVA type) and an IPS type. Further, optical film of this invention is superior in flatness and preferably utilized in various displays such as a plasma display, a field emission display, an organic EL display, an inorganic EL display and electronic paper. Particularly, in a liquid crystal display having an image plane as large as not less than 30 type, specifically of 30-54 type, no white spots are generated in the circumference portion of an image plane and the effect is maintained for a long period and is significant in a MVA type liquid crystal display. Particularly, observed are effects of decreased color unevenness, glare and wavy unevenness, as well as of little fatigue even with a long time viewing.

### EXAMPLES

In the following, this invention will be specifically explained with reference to examples, however, is not limited thereto.

### Example 1

### Preparation of Cellulose Ester Film 1

### (Silicon Dioxide Dispersion A)

| | |
|---|---|
| Aerosil 972V (produced by Nippon Aerosil Co., Ltd.) | 12 weigh parts |
| (mean diameter of primary particle of 16 nm, apparent | |
| specific gravity of 90 g/L) | |
| Ethanol | 88 weight parts |

The above composition was dispersed by a Manton-Gaulin homogenizer after having been mixed with stirring by a dissolver for 30 minutes. The solution turbidity after dispersion was 200 ppm. Methylene chloride of 88 weight parts was charged with stirring into silicon dioxide dispersion, and the resulting dispersion was mixed with stirring for 30 minutes by use of a dissolver, whereby silicon dioxide dispersion diluted solution A was prepared.

### (Preparation of Inline Addition Solution A)

| | |
|---|---|
| Tinuvin 109 (produced by Ciba Specialty Chemicals | 11 weight parts |
| Co., Ltd.) | |
| Tinuvin 171 (produced by Ciba Specialty Chemicals | 5 weight parts |
| Co., Ltd.) | |
| Methylene chloride | 100 weight parts |

The above components were charged into a sealable vessel, being heated, and completely dissolved with stirring, followed by being filtered.

Silica dioxide dispersion A of 36 weight parts was added to the above-prepared solution with stirring, 6 weight parts of cellulose acetate propionate (having an acetyl group substitution degree of 1.9 and a propionyl group substitution degree of 0.8) being added with stirring after 30 minutes stirring, and the resulting solution was filtered through polypropylene wound cartridge filter TCW-PPS-1N, produced by Advantech Toyo Co., Ltd., after stirring for further 60 minutes, whereby inline additive solution A was prepared.

### (Preparation of Dope A)

| | |
|---|---|
| Cellulose Ester (cellulose triacetate synthesized from | 100 weight parts |
| linter cotton, Mn = 148,000, Mn = 310,000, and | |
| Mw/Mn = 2.1, an acetyl substitution degree of 2.92) | |
| Trimethylolpropane tribenzoate | 5.0 weight parts |
| Ethylphthalyl ethylglycol | 5.5 weight parts |
| Methylene chloride | 440 weight parts |
| Ethanol | 40 weight parts |

The above components were charged into a sealable vessel, being heated, and completely dissolved with stirring, followed by being filtered through Azumi Filter Papar No. 24, whereby dope solution A was prepared.

Dope A was filtered through Finemet NF, produced by Nippon Seisen Co., Ltd., in a casting line. Inline addition solution A was filtered through Finemet NF, produced by Nippon Seisen Co., Ltd., in an inline addition solution line. Filtered dope A of 100 weight parts, which was added with 3 weight parts of inline addition solution A, was sufficiently mixed through an inline mixer (Toray Static Type Inline Mixer Hi-Mixer SWJ), and then uniformly cast on a stainless band support at a width of 1.8 m and at a temperature of 32° C. by use of a belt casting apparatus. Solvents were evaporated on a stainless band support until the residual solvent amount reached 100% and the web was peeled off from the stainless steel band support. Solvents of the peeled-off web of the cellulose ester was evaporated at 35° C., and the web was slit into a width of 1.65 m, followed by being dried at a drying temperature of 135° C. while being stretched by a tenter in the TD direction (the direction perpendicular to the film conveying direction) by 1.05 times. Herein, the residual solvent amount when stretching by a tenter started was 20%.

Thereafter, drying was completed while the web was conveyed with many rollers through drying zones of 120° C. and 130° C., being slit into a width of 1.4 m, being subjected to a knurling treatment of 1 cm wide having a mean height of 8 μm, and was wound around a core having an inner diameter of 15.2 cm (6 inches) at a winding tension of 220 N/m and terminal tension of 110 N/m, whereby cellulose ester film 1 was prepared. The stretching magnification in the MD direction (the direction same as the film conveying direction) immediately after peeled off, which was calculated from a rotation speed of a stainless band support and a driving speed of a tenter, was 1.07 times. A mean layer thickness of cellulose ester film 1 was 40 μm, and the roll length was 3,000 m.

<Treatment of Immersing Film in Processing Solution or of Spraying Film with Processing Solution: C-1-C-14>

By utilizing cellulose ester film 1 prepared above, by use of an apparatus of FIG. 1, under a condition of an ozone water concentration of 10 ppm, a hydrogen water concentration of 1.0 ppm, a processing solution temperature of 30° C. and without ultrasonic oscillator 106, long length roll-film was immersed while keeping a conveying speed of cellulose ester film at 15 m/min, whereby processed cellulose ester film 1 was prepared.

Next, processed cellulose ester film C-2-C-5 were prepared in a similar manner with varying ozone water concentration, hydrogen water concentration, processing solution temperature and presence or absence of an ultrasonic oscillator (ultrasonic oscillators 106 (having special specifications, produced by Nippon Alex Corp.) were arranged by two sets in the film width direction and 4 sets in a raw along the film conveying direction in the case of presence. The size of the one set of oscillator is 50 cm in the film width direction and 30 cm in the conveying direction, and the one set outputs ultrasonic waves of 100 kHz at 1,000 W.), as shown in Table 2.

Further, processed cellulose ester film C-6 was prepared by ozone water and hydrogen water each were sprayed from ozone water ejection nozzle 107 and hydrogen water ejection nozzle 108, respectively, under a condition of an ozone water concentration of 10 ppm, an ozone water temperature of 40° C., a hydrogen water concentration of 1.0 ppm, a hydrogen water temperature of 40° C., in the presence of ultrasonic waves and a conveying speed of cellulose ester film of 15 m/min, by use of an apparatus of FIG. 2. As hydrogen water ejection nozzle 108, utilized a megasonic nozzle (Pulsjet, produced by Honda Electronics Co., Ltd.) to irradiate ultrasonic waves of 1 MHz. Processed cellulose ester film C-7 and C-8 were prepared in a similar manner, with varying an ozone water concentration and a hydrogen water concentration as described in Table 2.

Further, processed cellulose ester film C-9-C-14, in which ozone water and hydrogen water each were utilized alone, were prepared in a similar manner, by use of apparatuses of FIG. 3 and FIG. 4 and under conditions described in Table 2.

<Treatment to Rub Film Surface with Elastic Body Wetted by Processing Solution: C-15-C-34>

By utilizing cellulose ester film 1 prepared above, treatment to rub the film surface with en elastic body wetted by a processing solution was carried out according to the following specification.

One side surface of long length roll-film was rubbed by elastic body 1 wetted by a processing solution by use of a film conveying apparatus shown in FIG. 5. The details of a utilized elastic body are as follows.

Material of elastic body: an aluminum roller having a diameter of 20 cm was covered with acrylonitrile•butadiene rubber having a thickness of 5 mm

Hardness of elastic body: a rubber hardness of 30 (measured by use of Durometer A Type, according to a method of JIS-K-6253)

Size of elastic body: a roller diameter of 20 cm

Change of friction coefficient of elastic body: The surface of an elastic body, after having been sufficiently washed with petroleum benzine, was coated with a 5 weight % trichloroisocyanuric acid solution by contacting weste soaked with a 5 weight % trichloroisocyanuric acid solution dissolved in acetic ethylester while rotating the elastic body. This elastic body was dried at room temperature as it is to evaporate a solvent in approximately 0.5 hours resulting in drying of the surface. A friction coefficient of an elastic body was changed as shown in Tables 3 and 4 by varying the concentration of trichloroisocyanuric acid solution. Herein, a static friction coefficient was measured based on the aforesaid method by use of “Heidon Surface Analyzer 14 Type”, manufactured by Shinto Scientific Co., Ltd.

Driving direction and rotation number of elastic body: rotation in the reverse direction against the film conveying direction, a rotation number of 10 rpm

Temperature of elastic body: 40° C.

Conveying speed of cellulose ester film was 15 m/min.

The types of processing solutions [(1), (2) and (3)] are described in Table 3. Further, as processing solution supply means 8 and 9, a bar-shaped nozzles of 140 cm long was arranged along the film width direction, the top opening having a clearance of 1 mm being utilized, and a processing solution was ejected on the film surface at the positions of processing solution supply means 8 and 9 at a flow rate of 30 L/min. As filter 10, one available on the market having a pore size of 0.2 mm was utilized. When hydrogen water is ejected from processing solution supply means 8 and 9, a megasonic nozzle (Puls Jet, manufactured by Honda Electronics Co., Ltd.) was employed to irradiate ultrasonic waves of 1 MHz.

In air supply on the film rear surface by air nozzle 5, a supplied air pressure was adjusted so as to make 3.0×10² Pa as a film plane pressure against an elastic body.

Two sets of ultrasonic oscillators 106 (an apparatus having special specifications, manufactured by Nippon Alex Corp.) were arranged along the film width direction in a raw. One set of this oscillator had a size of 50 cm in the film width direction and 30 cm in the film conveying direction, and adjusted to output ultrasonic waves of 100 KHz at a power of 1,000 W.

Herein, each one set of an edge position controller (EPC) was arranged at the upper stream by 10 m and the down stream by 10 m of the apparatus along the film conveying pass to control the position of long length roll-film which was being rubbed by an elastic body.

Under the above conditions, processed cellulose ester film. C-15-C-30 were prepared by changing types of processing solutions [(1), (2) and (3)], ozone water concentration, hydrogen water concentration and friction coefficient of an elastic body, as described in Table 3.

Further, processed cellulose ester film C-31-C-34 were prepared by continuously subjecting long length roll-film to a treatment to be rubbed with ozone water and hydrogen water in a separate baths by use of an apparatus of FIG. 8, while changing an ozone water concentration, a hydrogen water concentration and presence of ultrasonic waves as shown in Table 4.

Herein, with respect to cellulose ester film C-21, utilized is a processing solution comprising ozone water added with 50 ppm of a carbonic acid gas.

Herein, the details of the items described in Table 1 with abbreviated numbers were as follows:

*1: Number of optical film provided with antireflection layer

*2: Number of processed cellulose ester film

*3: Ozone water+carbonic acid water

*4: Ozone water+hydrogen water

(Preparation of Optical Film Provided with Antireflection Layer)

Each optical film provided with an antireflection layer was prepared according to the following procedure employing processed cellulose ester film C-1-C-34 prepared above.

A refractive index of each layer constituting an antireflection layer was measured by the following method.

### (Refractive Index)

The refractive index of each refractive index layer was determined from the measurement results of a spectral reflectance by a spectrophotometer with respect to samples, in which each layer coated alone on hard coat film, prepared below. The rear surface to the measurement side was subjected to a light absorbing treatment by use of a spray after having been roughening treated to prevent light reflection on the rear surface, and the reflectance in a visible light region (400-700 nm) was measured under a condition of specular reflection at 5 degrees employing a spectrophotometer U-4000 Type (manufactured by Hitachi, Ltd.).

### (Particle Size of Metal Oxide Micro-Particles)

The particle size of utilized metal oxide micro-particles was determined by observing each 100 micro-particles through an electronmicroscope (SEM) to define the diameter of a circumcircle of each micro-particle as a particle size, an average value of which was calculated.

### <Formation of Hard Coat Layer>

The following coating solution for a hard coat layer was filtered through a polypropylene filter having a pore size of 0.4 μm to prepare a hard coat layer coating solution, which was coated on cellulose ester film C-1-C-34 having been processed above by use of a gravure coater, and the coated layer was cured by use of an ultraviolet lamp at an illuminance at the irradiated portion of 100 mW/cm² and an irradiation quantity of 0.1 J/cm², whereby a hard coat layer having a dry layer thickness of 7 μm was formed resulting in preparation of hard coat film.

### (Hard Coat Layer Coating Solution)

The following materials were mixed with stirring to prepare a hard coat layer coating solution.

| | |
|---|---|
| Acrylic monomer; KAYARAD DPHA | 220 weight parts |
| (dipentaerythritol hexaacrylate, produced by Nippon | |
| Kayaku Co., Ltd.) | |
| Irgacure 184 (produced by Ciba Specialty Chemicals | 20 weight parts |
| Co., Ltd.) | |
| Propyleneglycol monomethylether | 110 weight parts |
| Ethyl acetate | 110 weight parts |

<Preparation of Polarizer Protective Film Provided with Antireflection Layer>

A high refractive index layer, and successively a low refractive index layer in this order were coated as antireflection layers in the following manner on the hard coat film prepared above, whereby optical film provided with an antireflection layer 1-34 were prepared.

### (Formation of Antireflection Layer; High Refractive Index Layer)

The following high refractive index layer coating composition was coated on hard coat film by use of an extrusion coater and dried at 80° C. for 1 minute, then the coated layer was cured by irradiation of ultraviolet rays at 0.1 J/cm², followed by being further thermally cured at 100° C. for 1 minute, whereby a high refractive index layer having a thickness of 78 nm was prepared.

The refractive index of this high refractive index layer was 1.62.

### (High Refractive Index Layer Coating Composition)

| | |
|---|---|
| Isopropyl alcohol solution of metal oxide micro- | 55 weight parts |
| particles (solid content of 20%, ITO particles, | |
| particle size of 5 nm) | |
| Metal compound: Ti(OBu)₄ (tetra-n-butoxytitane) | 1.3 weight parts |
| Ionizing radiation curable resin: dipentaerythritol | 3.2 weight parts |
| hexaacrylate | |
| Photoinitiator: Irgacure 184 (produced by Ciba | 0.8 weight parts |
| Specialty Chemicals Co., Ltd.) | |
| 10% propyleneglycol monomethylether solution of | 1.5 weight parts |
| straight chain dimethylsilicone-EO block copolymer | |
| (FZ-2207, produced by Nippon Unicar Co., Ltd.) | |
| Propyleneglycol monomethylether | 120 weight parts |
| Isopropyl alcohol | 240 weight parts |
| Methyl ethyl ketone | 40 weight parts |

### (Formation of Antireflection Layer; Low Refractive Index Layer)

The following low refractive index layer coating composition was coated on the aforesaid high refractive index layer by use of an extrusion coater and dried at 100° C. for 1 minute, then the coated layer was cured by irradiation of ultraviolet rays at 0.1 J/cm², being wound on a heat resistant plastic core at a roll length of 4,000 m, followed by being subjected to a thermal treatment at 80° C. for 3 days, whereby optical film 1-34 provided with an antireflection layer were prepared.

Herein, this low refractive index layer had a thickness of 95 nm and a refractive index of 1.37.

### (Preparation of Low Refractive Index Layer Coating Composition)<

### Preparation of Tetraethoxysilne Hydrolyzed Product A>

Tetraethoxysilane of 289 g and 553 g of ethanol were mixed, 157 g of a 0.15% acetic acid aqueous solution being added thereto, and the resulting solution was stirred for 30 hours in a water bath at 25° C. to prepare hydrolyzed product A.

| | |
|---|---|
| Tetraethoxysilane hydrolyzed product A | 110 weight parts |
| Hollow silica type micro-particles described below | 30 weight parts |
| KBM503 (silane coupling agent, produced by | 4 weight parts |
| Shin-Etsu Chemical Co., Ltd.) | |
| 10% propyleneglycol monomethylether solution of | 3 weight parts |
| straight chain dimethylsilicone-EO block copolymer | |
| (FZ-2207, produced by Nippon Unicar Co., Ltd.) | |
| Propyleneglycol monomethylether | 400 weight parts |
| Isopropyl alcohol | 400 weight parts |

### <Preparation of Hollow Silica Type Micro-Particles>

A mixture of silica sol, having a mean particle size of 5 nm and a SiO₂ concentration of 20 weight %, of 100 g and 1900 g of pure water was heated at 80° C. The pH of this reaction mother solution was 10.5, and into the mother solution 9000 g of a sodium silicate aqueous solution of 0.98 weight as SiO₂, and 9000 g of sodium aluminate aqueous solution of 1.02 weight % as Al₂O₃ were simultaneously added. Meanwhile, the temperature of the reaction solution was kept at 80° C. The pH of the reaction solution was raised to 12.5 immediately after addition and barely changed thereafter. After finishing the addition, the reaction solution was cooled to room temperature and washed with an ultra-filtration membrane to prepare a SiO₂•Al₂O₃ nucleus particle dispersion having a solid concentration of 20 weight % (process (a)).

To this nucleus particle dispersion of 500 g, 1700 g of pure water were added and the resulting solution was heated at 98° C., and 3000 g of a silicic acid solution (SiO₂ concentration of 3.5 weight %), which were prepared by dealkalization of a sodium silicate aqueous solution by use of cationic ion exchange resin, were added while keeping this temperature, whereby a dispersion of nucleus particles provided with the first silica cover layer, were prepared (process (b)).

Successively, 500 g of nucleus particle dispersion provided with the first silica cover layer, a solid concentration of which became 13 weight % by washing with an ultrafiltration membrane, were added with 1125 g of pure water, and further being titrated with concentrated hydrochloric acid to make pH of 1.0 to perform dealuminum treatment. Next, aluminum salt, which had been dissolved, was removed by use of an ultrafiltration membrane while adding 10 L of a hydrochloric acid aqueous solution having a pH of 3 and 5 L of pure water, and a dispersion of SiO₂•Al₂O₃ porous particles provided with the first silica cover layer, a part of constituent components of which is removed, were prepared (process (c)).

After heating a mixed solution comprising 1500 g of the above-described porous particle dispersion, 500 g of pure water, 1750 g of ethanol and 626 g of 28% ammonium water at 35° C., 104 g of ethyl silicate (28 weight % SiO₂) was added and the surface of porous particles, on which the first silica cover layer had been formed, were covered with a hydrolysis polycondensation product to form the second silica cover layer. Successively, a dispersion of hollow silica type micro-particles having a solid concentration of 20 weight % was prepared by substituting the solvent into ethanol by use of an ultrafiltration membrane.

A thickness of the first silica cover layer of this hollow silica type micro-particle was 3 nm, a mean particle size was 47 nm, a MO_{X}/SiO₂ (mol ratio) was 0.0017, and a refractive index was 1.28. Herein, a mean particle size was measured by means of a dynamic light scattering method.

### <Evaluation>

The following evaluations were carried out utilizing prepared optical film 1-34 provided with an antireflection layer.

### (Evaluation of Resistance to Wrinkling)

Each 10 rolls of optical film provided with an antireflection layer were visually observed at a winding station to evaluate the presence of wrinkles based on the following criteria.

A: No generation of wrinkles was recognized at all in any of 10 rollers.

B: Slight generation of wrinkles was recognized with not more than 1-3 rolls.

C: Clear generation of wrinkles was recognized with not more than 1-3 rolls.

D: Clear generation of wrinkles was recognized with not less than 4 rolls.

### (Evaluation of Resistance to Color Unevenness)

A sample having a size of 1 m² was cut out from each of 10 rolls of optical film provided with an antireflection layer, a black acryl plate being pasted up on the surface opposite to the side coated with an antireflection layer and the antireflection layer coated surface was irradiated with a three-wavelength light source, whereby the generation and intensity of color unevenness were visually evaluated.

A: No color unevenness was recognized.

B: Weak color unevenness was recognized in 1-3 m² among 10 m².

C: Color unevenness was recognized in 1-3 m² among 10 m².

D: Color unevenness was recognized in not less than 4 m² among 10 m².

### (Evaluation of Resistance to Discontinuous Streaks)

A sample having a size of 1 m² was cut out from each of 10 rolls of optical film provided with an antireflection layer, a black acryl plate being pasted up on the surface opposite to the side coated with an antireflection layer and the antireflection layer coated surface was irradiated with a three-wavelength light source, whereby generation of discontinuous streaks and the number of generated streaks were evaluated. The number of streaks is an averaged value with respect to 10 m².

Discontinuous streaks are straight and discontinuous streaks generated along the conveying direction, and the color of reflective light at the streak portion looks different from other portion. The length of one line of a discontinuous streak is approximately 50-200 mm.

A: none

B: 1-2 lines

C: 3-5 lines

D: not less than 6 lines

The above evaluation results are shown in Tables 2-4.

TABLE 2

| | | Processing solution | | | | | | | | Evaluation results | | | |
|---|---|---|---|---|---|---|---|---|---|---|---|---|---|
| | | configuration | | | Ozone | Hydrogen | | | | | Resistance | Resistance | |
| | | | 1st | 2nd | water | water | | | | Resistance | to | to dis- | |
| | | Apparatus | processing | processing | concentration | concentration | | | | to | color | continuous | |
| *1 | *2 | No. | tank | tank | (ppm) | (ppm) | *3 | *4 | *5 | Wrinkling | unevenness | streaks | Remarks |
| 1 | C-1 | FIG. 1 | Ozone water | Hydrogen | 10 | 1.0 | 30 | No | — | B | B | C | Inv. |
| | | | | water | | | | | | | | | |
| 2 | C-2 | FIG. 1 | Ozone water | Hydrogen | 10 | 1.0 | 30 | Yes | — | B | B | B | Inv. |
| | | | | water | | | | | | | | | |
| 3 | C-3 | FIG. 1 | Ozone water | Hydrogen | 10 | 1.0 | 20 | Yes | — | B | C | B | Inv. |
| | | | | water | | | | | | | | | |
| 4 | C-4 | FIG. 1 | Ozone water | Hydrogen | 25 | 1.5 | 30 | Yes | — | B | B | B | Inv. |
| | | | | water | | | | | | | | | |
| 5 | C-5 | FIG. 1 | Ultra-pure | Ultra-pure | 0 | 0 | 30 | Yes | — | D | D | D | Comp. |
| | | | water | water | | | | | | | | | |
| 6 | C-6 | FIG. 2 | Ozone water | Hydrogen | 10 | 1.0 | 40 | Yes | — | B | B | B | Inv. |
| | | | | water | | | | | | | | | |
| 7 | C-7 | FIG. 2 | Ozone water | Hydrogen | 25 | 1.5 | 40 | Yes | — | B | B | B | Inv. |
| | | | | water | | | | | | | | | |
| 8 | C-8 | FIG. 2 | Ultra-pure | Ultra-pure | 0 | 0 | 40 | Yes | — | D | D | D | Comp. |
| | | | water | water | | | | | | | | | |
| 9 | C-9 | FIG. 3 | Ozone water | — | 10 | — | 40 | No | — | B | B | C | Inv. |
| 10 | C-10 | FIG. 3 | Ozone water | — | 25 | — | 40 | No | — | B | B | C | Inv. |
| 11 | C-11 | FIG. 3 | Ultra-pure | — | 0 | — | 40 | No | — | D | D | D | Comp. |
| | | | water | | | | | | | | | | |
| 12 | C-12 | FIG. 4 | Hydrogen | — | — | 1.0 | 40 | Yes | — | B | C | B | Inv. |
| | | | water | | | | | | | | | | |
| 13 | C-13 | FIG. 4 | Hydrogen | — | — | 1.5 | 40 | Yes | — | B | C | B | Inv. |
| | | | water | | | | | | | | | | |
| 14 | C-14 | FIG. 4 | Ultra-pure | — | — | 0 | 40 | Yes | — | D | D | D | Comp. |
| | | | water | | | | | | | | | | |

*3: Processing solution temperature (° C.),
*4: Irradiation of ultrasonic wave
*5: Friction coefficient of elastic body,
Inv.: Invention,
Comp.: Comparison

TABLE 3

| | | | | | | | Hydrogen |
|---|---|---|---|---|---|---|---|
| | | Processing solution configuration (FIG. 5) | | | | Ozone water | water |
| | | Apparatus | Supply means | Supply means | Processing | concentration | concentration |
| *1 | *2 | No. | (1) | (2) | tank (3) | (ppm) | (ppm) |
| 15 | C-15 | FIG. 5 | Ozone water | Ozone water | Ozone water | 10 | — |
| 16 | C-16 | FIG. 5 | Ozone water | Ozone water | Ozone water | 10 | — |
| 17 | C-17 | FIG. 5 | Ozone water | Ozone water | Ozone water | 0.3 | — |
| 18 | C-18 | FIG. 5 | Ozone water | Ozone water | Ozone water | 5 | — |
| 19 | C-19 | FIG. 5 | Ozone water | Ozone water | Ozone water | 25 | — |
| 20 | C-20 | FIG. 5 | Ozone water | Ozone water | Ozone water | 25 | — |
| 21 | C-21 | FIG. 5 | *3 | *3 | *3 | 0.3 | — |
| 22 | C-22 | FIG. 5 | Hydrogen water | Hydrogen water | Hydrogen | — | 0.3 |
| | | | | | water | | |
| 23 | C-23 | FIG. 5 | Hydrogen water | Hydrogen water | Hydrogen | — | 0.5 |
| | | | | | water | | |
| 24 | C-24 | FIG. 5 | Hydrogen water | Hydrogen water | Hydrogen | — | 1.0 |
| | | | | | water | | |
| 25 | C-25 | FIG. 5 | Hydrogen water | Hydrogen water | Hydrogen | — | 1.5 |
| | | | | | water | | |
| 26 | C-26 | FIG. 5 | Ultra-pure | Ultra-pure | Ultra-pure | — | 0 |
| | | | water | water | water | | |
| 27 | C-27 | FIG. 5 | Ozone water | Hydrogen water | *4 | 10 | 1.0 |
| 28 | C-28 | FIG. 5 | Ozone water | Hydrogen water | *4 | 25 | 1.5 |
| 29 | C-29 | FIG. 5 | Ozone water | Hydrogen water | *4 | 25 | 1.5 |
| 30 | C-30 | FIG. 5 | Ozone water | Hydrogen water | *4 | 25 | 1.5 |

| | Processing | Irradiation | Friction | Evaluation results | | | |
|---|---|---|---|---|---|---|---|
| | solution | of | coefficient | Resistance | Resistance | Resistance to | |
| | temperature | ultrasonic | of elastic | to | to color | discontinuous | |
| *1 | (° C.) | wave | body | Wrinkling | unevenness | streaks | Remarks |
| 15 | 40 | Yes | 0.5 | A | A | B | Invention |
| 16 | 40 | Yes | 0.7 | A | A | B | Invention |
| 17 | 40 | Yes | 0.7 | A | B | B | Invention |
| 18 | 40 | Yes | 0.7 | A | A | B | Invention |
| 19 | 40 | Yes | 0.7 | A | A | B | Invention |
| 20 | 60 | Yes | 0.7 | A | A | B | Invention |
| 21 | 40 | Yes | 0.7 | A | A | B | Invention |
| 22 | 40 | Yes | 0.7 | A | B | B | Invention |
| 23 | 40 | Yes | 0.7 | A | B | A | Invention |
| 24 | 40 | Yes | 0.9 | A | B | A | Invention |
| 25 | 40 | Yes | 0.7 | A | B | A | Invention |
| 26 | 40 | Yes | 0.7 | A | D | D | Comparison |
| 27 | 40 | Yes | 0.7 | A | A | A | Invention |
| 28 | 40 | Yes | 0.2 | A | A | A | Invention |
| 29 | 40 | Yes | 0.7 | A | A | A | Invention |
| 30 | 40 | Yes | 0.3 | A | A | A | Invention |

TABLE 4

| | | Processing solution | | | | | | | | Evaluation results | | | |
|---|---|---|---|---|---|---|---|---|---|---|---|---|---|
| | | configuration | | | Ozone | Hydrogen | | | | | Resistance | Resistance | |
| | | Ap- | 1st | 2nd | water | water | | | | Resistance | to | to | |
| | | paratus | processing | processing | concentration | concentration | | | | to | color | discontinuous | |
| *1 | *2 | No. | tank | tank | (ppm) | (ppm) | *3 | *4 | *5 | Wrinkling | unevenness | streaks | Remarks |
| 31 | C-31 | FIG. 8 | Ozone | Hydrogen | 10 | 1.0 | 40 | No | 0.5 | A | A | B | Inv. |
| | | | water | water | | | | | | | | | |
| 32 | C-32 | FIG. 8 | Ozone | Hydrogen | 10 | 1.0 | 40 | Yes | 0.5 | A | A | A | Inv. |
| | | | water | water | | | | | | | | | |
| 33 | C-33 | FIG. 8 | Ozone | Hydrogen | 25 | 1.5 | 40 | Yes | 0.5 | A | A | A | Inv. |
| | | | water | water | | | | | | | | | |
| 34 | C-34 | FIG. 8 | Ultra-pure | Ultra-pure | 0 | 0 | 40 | Yes | 0.5 | A | D | D | Comp. |
| | | | water | water | | | | | | | | | |

*3: Processing solution temperature (° C.),
*4: Irradiation of ultrasonic wave
*5: Friction coefficient of elastic body,
Inv.: Invention,
Comp.: Comparison

It is clear from Tables 2-4 that optical film provided with an antireflection layer utilizing processed cellulose ester film of this invention C-1-C-4, C-6-C-7, C-9-C-10, C-12-C-13, C-15-C-25, and C-27-C-33 has been improved with respect to wrinkles, color unevenness and discontinuous streaks compared to comparative examples. Further, it is clear that C-15-C-25, and C-27-C-33, which have been subjected to a treatment to continuously rub long length roll-film in contact with a processing solution with an elastic body, exhibit further improved effects of this invention.

Further, it is clear that ozone water has a higher effect to restrain color unevenness and hydrogen water has a higher effect to minimize discontinuous streaks, respectively, so that combined utilization of ozone water and hydrogen water and rubbing of film with an elastic body can improve all the characteristics with respect to wrinkles, color unevenness and discontinuous streaks.

### Example 2

A polarizer and a liquid crystal display were prepared employing optical film 1-34 provided with an antireflection layer.

### <Preparation of Polarizer>

Polyvinyl alcohol film having a thickness of 120 μm was uniaxially stretched (at a temperature of 110° C. and a stretching magnification of 5 times). The resulting film was immersed in an aqueous solution, comprising 0.075 g of iodine, 5 g of potassium iodide and 100 g of water, for 60 seconds, and successively, in an aqueous solution of 68° C. which was comprised of 6 g of potassium iodide, 7.5 g of boric acid and 100 g of water. The film was washed with water, and dried to prepare polarizing film.

Next, polarizing film and optical film 1-34 provided with an antireflection layer prepared in example 1 and cellulose ester film as a rear surface polarizer protective film were pasted up according to following processes 1-5, to prepare a polarizer. As rear surface polarizer protective film, cellulose ester film having a phase difference (Konica Minolta TAC KC8UCR-5, produced by Konica Minolta Opt, Inc.) was utilized to form each polarizer.

Process 1: Cellulose ester film was immersed in a 2 mol/L sodium hydroxide solution at 60° C. for 60 seconds, being washed with water, and dried to prepare optical film provided with an antireflection layer the side of which to be pasted up with polarizer had been saponificated.

Process 2: The aforesaid polarizing film was immersed in a polyvinyl alcohol adhesive tank having a solid content of 2 weight % for 1-2 seconds.

Process 3: An excess adhesive on polarizing film, adhered in process 2, was roughly removed by wiping, and the resulting film was arranged on optical film provided with an antireflection layer having been treated in process 1 to be accumulated.

Process 4: Optical film provided with an antireflection layer prepared above by being accumulated in process 3, polarizing film and cellulose ester film of the rear surface side were pasted up at a pressure of 20-30 N/cm² and a conveying speed of approximately 2 m/min.

Process 5: A sample comprising an accumulate of polarizing film, optical film provided with an antireflection layer and back side cellulose ester film, which were prepared in process 4, was dried in a dryer at 80° C. for 2 minutes, whereby a polarizer was prepared. Polarizers 1-34 were prepared by utilizing each optical film provided with an antireflection layer 1-34.

### <Preparation of Liquid Crystal Display>

A liquid crystal display for viewing angle measurement was prepared in the following manner and characteristics as a liquid crystal display thereof were evaluated.

The polarizers having been pasted up on the both surfaces in advance, in 15 Type Display VL-150 SD manufactured by Fujitsu Ltd. were peeled off and the above-prepared polarizers 1-34 each were pasted up on the glass plane of a liquid crystal cell.

At that time, the pasting direction of a polarizer is adjusted so as to be the same direction of the polarizers having been pasted up in advance, whereby liquid crystal displays 1-34 each were prepared.

The following evaluations were performed utilizing liquid crystal displays 1-34 prepared in the above manner.

### <Evaluation>

### <Evaluation of Visual Recognition>

After each of the above-prepared liquid crystal displays have been kept under a condition of 60° C. and 90% RH for 100 hours, the condition was returned to 23° C. and 55% RH. After that, visual recognition was evaluated based on the following criteria. As a result, when the surface of a display is observed, all the liquid crystal displays utilizing optical film provided with an antireflection layer of this invention showed evaluation rank A or B to be excellent in flatness, while comparative liquid crystal displays showed evaluation rank C or D providing minute wavy unevenness and liable to cause fatigue of eyes at long period viewing.

A: No wavy unevenness on the surface was recognized at all.

B: Slight wavy unevenness on the surface was recognized.

C: Some minute wavy unevenness on the surface was recognized.

D: Minute wavy unevenness on the surface was recognized.

1. A processing method of an optical film comprising the step of:
subjecting a long length roll-film continuously conveyed to a treatment so as to be brought in contact with a processing solution containing at least one type of gas selected from reducing gas and oxidizing gas.

2. The processing method of the optical film described in claim 1,
wherein the reducing gas is hydrogen gas and the oxidizing gas is ozone gas.

3. The processing method of the optical film described in claim 1,
wherein a dissolved hydrogen concentration of the processing solution is 0.1-2 ppm based on the total weight of the processing solution.

4. The processing method of the optical film described in claim 1,
wherein an ozone concentration of the processing solution is 0.1-100 ppm based on the total weight of the processing solution.

5. The processing method of the optical film described in claim 1
wherein the processing solution is irradiated by ultrasonic waves while the long length roll-film is brought in contact with the processing solution.

6. The processing method of the optical film described in claim 1,
wherein provided is a process to continuously rub the long length roll-film having been contacted with the processing solution by an elastic body.

7. The processing method of the optical film described in claim 6,
wherein a static friction coefficient of the surface of the elastic body is not less than 0.2 and not more than 0.9.

8. The processing method of the optical film described in claim 6,
wherein provided is a means to adjust a conveying position by detecting a position of the edge portion in the width direction of the long length roll-film.

9. The processing method of the optical film described in claim 6,
wherein a temperature of the processing solution is not lower than 30° C. and not higher than 70° C., and a temperature of the elastic body is not lower than 30° C. and not higher than 70° C.

10. The processing method of the optical film described in claim 6,
wherein the long length roll-film is rubbed by the elastic body while pressing a rear surface of the long length roll-film.

11. The processing method of the optical film described in claim 6,
wherein the surface to be processed of the long length roll-film is wetted in advance by the processing solution before being rubbed with an elastic body having been wetted by the processing solution.

12. The processing method of the optical film described in claim 11,
wherein the surface to be processed of the long length roll-film is wetted by a means to supply the processing solution to the surface to be processed of the long length roll-film.

13. The processing method of the optical film described in claim 11,
wherein a means to supply the processing solution is provided between the long length roll-film and the elastic body.

14. The processing method of the optical film described in claim 1,
wherein a period of the surface to be processed of the long length roll-film being wetted is not shorter than 2 seconds and not longer than 60 seconds.

15. The processing method of the optical film described in claim 1,
wherein a layer thickness of the long length roll-film is not less than 30 μm and not more than 200 μm.

16. An optical film being processed by the processing method of the optical film described in claim 1.

17. A processing device of the optical film, which is provided with an elastic body rubbing means to rub long length roll-film with an elastic body having been wetted by a processing solution and a processing solution removing means to remove a processing solution on the surface of the long length roll-film after rubbing while the film is continuously conveyed,
wherein provided is a means to make the processing solution contain at least one type of gas selected from reducing gas and oxidizing gas.
